(19) United States
(12) Patent Application Publication
(10) Pub. No.: US 2026/0010701 A1
(43) Pub. Date: Jan. 8, 2026

(54) OPTIMIZATION OF WIRE-CUTTING OF QUANTUM CIRCUITS

(71) Applicant: International Business Machines Corporation, Armonk, NY (US)

(72) Inventors: Takashi Ido, Bunkyo-ku (JP); Hitomi Chiba, Toshima-ku (JP); IKKO HAMAMURA, Tokyo (JP); Hiroshi Horii, Tokyo (JP)

(21) Appl. No.: 18/765,892

(22) Filed: Jul. 8, 2024

(51) Int. Cl. G06F 30/398; G06N 10/20

(52) U.S. Cl. CPC G06F 30/398; G06N 10/20

(57) ABSTRACT

A system comprises a memory that stores computer executable components, and a processor that executes the computer executable components stored in the memory, wherein the computer executable components comprise a generating component that generates a mixed integer linear programming (MILP) problem model representing a vertex of quantum subcircuits to be subdivided from a quantum circuit, and a subdividing component that identifies a wire-cutting edge of the quantum circuit using the MILP problem model and based on a decision variable that corresponds to the vertex.

### BACKGROUND

The subject disclosure relates to quantum circuit subdivision for execution of large quantum circuits using quantum computing systems.

### SUMMARY

The following presents a summary to provide a basic understanding of one or more embodiments described herein. This summary is not intended to identify key or critical elements, and/or to delineate scope of particular embodiments or scope of claims. Its sole purpose is to present concepts in a simplified form as a prelude to the more detailed description that is presented later. In one or more embodiments, systems, computer-implemented methods, apparatuses and/or computer program products described herein can provide for optimized wire-cutting of a quantum circuit.

In accordance with an embodiment, a system can comprise a memory that stores computer executable components, and a processor that executes the computer executable components stored in the memory, wherein the computer executable components comprise a generating component that generates a mixed integer linear programming (MILP) problem model representing a vertex of quantum subcircuits to be subdivided from a quantum circuit, and a subdividing component that identifies a wire-cutting edge of the quantum circuit using the MILP problem model and based on a decision variable that corresponds to the vertex.

In accordance with another embodiment, a computer-implemented method can comprise generating, by a system operatively coupled to a processor, a mixed integer linear programming (MILP) problem model representing a vertex of quantum subcircuits to be subdivided from a quantum circuit, and identifying, by the system, a wire-cutting edge of the quantum circuit using the MILP problem model and based on a decision variable that corresponds to the vertex.

In accordance with still another embodiment, a computer program product, facilitating a process to determine a quantum circuit wire-cutting solution, can comprise a computer readable storage medium having program instructions embodied therewith, the program instructions executable by a processor to cause the processor to generate, by the processor, a mixed integer linear programming (MILP) problem model representing a vertex of quantum subcircuits to be subdivided from a quantum circuit, and identify, by the processor, a wire-cutting edge of the quantum circuit using the MILP problem model and based on a decision variable that corresponds to the vertex.

A benefit of the system, computer-implemented method and/or computer program product can be an ability to provide for significant reduction of a number of variables and/or number of constraints in an optimized MILP problem model compared use of an existing framework for wire-cutting solution. The one or more frameworks discussed herein can thus allow for planning of wire-cutting of a quantum circuit in a reduced time, provision of a solution of higher quality, and/or provision of a solution with a smaller reconstruction cost, as compared to use of an existing framework for wire-cutting solution. In one or more cases, the one or more embodiments described herein also can allow for planning of wire-cutting of a larger quantum circuit that can be possible with use of an existing framework for wire-cutting solution. This can be because the proposed method can express the same constraints as the existing framework does with fewer variables and fewer constraints. That is, a time to obtain an optimal solution using a MILP problem model generally increases exponentially with the number of variables and constraints.

Another benefit of the system, computer-implemented method and/or computer program product can be an ability to plan wire-cutting of quantum circuits much faster than via use of an existing framework. With respect to use of a quantum simulation, the one or more embodiments described herein can be employed to generate a wire-cutting solution for use in simulating a quantum circuit with about 30 or more qubits, or even more than about 100 or more qubits, using wire-cutting and state vector simulation. Indeed, while a state vector simulator cannot directly simulate such as quantum circuit directly due to memory size, wire-cutting executed by the one or more embodiments described herein can subdivide the quantum circuit into plural quantum subcircuits with tractable sizes.

### DESCRIPTION OF THE DRAWINGS

FIG. 1 illustrates a block diagram of an example, non-limiting system that can provide a process to determine a wire-cutting solution, in accordance with one or more embodiments described herein.

FIG. 2 illustrates a block diagram of another example, non-limiting system that can provide a process to determine a wire-cutting solution, in accordance with one or more embodiments described herein.

FIG. 3 illustrates a block diagram of a quantum system that can be employed in connection with the non-limiting systems of FIGS. 1 and 2, in accordance with one or more embodiments described herein.

FIG. 4 provides a schematic illustration of base wire-cutting, as can be modified by the system of FIG. 2, in accordance with one or more embodiments described herein.

FIG. 5 provides a schematic illustration of wire-cutting, as can be performed by the system of FIG. 2, in accordance with one or more embodiments described herein.

FIG. 6 provides a schematic illustration of wire-cutting, as can be performed by the system of FIG. 2, in accordance with one or more embodiments described herein.

FIG. 7 provides a schematic illustration of wire-cutting, as can be performed by the system of FIG. 2, in accordance with one or more embodiments described herein.

FIG. 8 provides a schematic illustration of wire-cutting, as can be performed by the system of FIG. 2, in accordance with one or more embodiments described herein.

FIG. 9 illustrates a flow diagram of one or more processes that can be performed by the non-limiting system of FIG. 2, to determine a wire-cutting solution, in accordance with one or more embodiments described herein.

FIG. 10 illustrates a flow diagram of one or more processes that can be performed by the non-limiting system of FIG. 2, to determine a wire-cutting solution, in accordance with one or more embodiments described herein.

FIG. 11 illustrates a continuation of the flow diagram of FIG. 10 of one or more processes that can be performed by the non-limiting system of FIG. 2, in accordance with one or more embodiments described herein.

FIG. 12 illustrates a block diagram of an example, non-limiting, computer environment in accordance with one or more embodiments described herein.

### DETAILED DESCRIPTION

The following detailed description is merely illustrative and is not intended to limit embodiments and/or application or utilization of embodiments. Furthermore, there is no intention to be bound by any expressed or implied information presented in the preceding Summary section, or in the Detailed Description section. One or more embodiments are now described with reference to the drawings, wherein like reference numerals are utilized to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

Briefly, a total cost (e.g., time, power, qubits employed) to execute a quantum circuit can depend on a number of qubits employed, number of gates to be executed, and/or depth of the quantum circuit. Often, a quantum circuit is too large (e.g., has too many gates in length or employes too many qubits in depth) to be performed on an available quantum system (e.g., having too small a number of qubits as compared to that required to execute the quantum circuit). To address this issue one or more proposed approaches are generally proposals only and can comprise gate-cutting and/or use of classical communication between subcircuits of a quantum circuit. As used herein, gate-cutting refers to dividing a quantum circuit into quantum subcircuits by cutting a multi-qubit gate of the quantum circuit. In few instances, these approaches can allow for execution of a larger quantum circuit on a smaller quantum system (e.g., comprising fewer qubits than required to execute the full larger quantum circuit as a single quantum circuit). However, even use of these approaches in the few instances does not make up for the deficiencies of these approaches. That is, these approaches can themselves be costly (e.g., time, power, qubits employed), inefficient, and/or only able to be employed on some types of quantum circuits (e.g., relating to the few instances only).

Accordingly, to address one or more deficiencies noted above, discussed herein is a wire-cutting approach for circuit subdivision of a quantum circuit. Wire-cutting of quantum circuit is an approach to cut virtual wires between quantum gates of a virtual quantum circuit to divide the original quantum circuits into plural quantum subcircuits.

As used herein, a virtual quantum circuit is a model of a quantum computation comprising qubits and quantum gates. As used herein, a wire schematically depicts a path along which quantum gates are executed in a specified order using a specified single qubit per wire. Accordingly, illustration of the wire and/or of the quantum circuit itself is not required for implementation of one or more embodiments discussed herein. Rather, the one or more embodiments can execute wire-cutting digitally without visual aid. However, illustration is provided herein to explain the one or more processes of the one or more embodiments. Additionally, and/or alternatively, generation of illustration of one or more virtual quantum circuits by the one or more embodiments herein can be helpful to a user entity using the one or more embodiments, such as to understand the processes performed by the one or more embodiments discussed herein and/or to aid in providing feedback to the one or more processes.

The one or more embodiments described herein can employ a novel optimization framework that can be scalable to an extent that surpasses scalability of conventional frameworks. With respect thereto, reconstruction cost, which is exponentially based upon a number of cuts, e.g., 4^{(number of cuts)}, is a dominant portion of a total cost of executing a quantum circuit using a wire-cutting framework described herein. Accordingly, minimization of a number of the cuts can be a focus of the one or more frameworks discussed herein, thereby allowing for the scalability. As used herein, the term reconstruction refers to consolidation of outcomes of plural quantum subcircuits to obtain one or more outcomes of the original quantum circuit.

In particular, quantum circuits can be represented by a DAG comprising both single-qubit gates and two-qubits gates. Note that quantum gates acting on more than two qubits can be transformed into a series of single-qubit gates and two-qubit gates. The one or more embodiments described herein focus on DAGs that ignore single-qubit gates in the context of wire-cutting because single qubit-gates do not affect the choice of wire-cutting positions. A vertex of the DAG represents a two-qubit gate and a (directed) edge of the DAG represent the two-qubit gate corresponding to the source vertex precedes the two-qubit gate corresponding to the destination vertex on one or more same qubits.

As used herein a DAG is a directed graph with no cycles, used to represent quantum circuits. As used herein, a directed graph is graph comprised of a set of vertices (e.g., arcs) connected by directed edges. A directed edge can be defined as a connection of two vertices, e.g., a source vertex and a destination vertex. An objective for use of a DAG can be to select edges that correspond to wire-cuts, in a manner such that the reconstruction cost can be minimized. In one or more cases, wire-cutting appends some initialization instructions and/or measurement instructions to the terminals of cuts of the subcircuits. As a result, such instructions can be executed with a quantum system or quantum simulator. Using the measurement readouts thereof, plural outcomes of the executions can be employed in combination to reconstruct a final outcome of the original quantum circuit. As noted above, the reconstruction cost can be proportional to 4\hat{ }(number of cuts) using a quantum system, or 2\hat{ }(number of qubits of subcircuits) where use of a state-vector-based quantum simulator is employed.

The one or more embodiments described herein can generally employ such wire-cutting method based on generation and/or use of a mixed integer linear programming (MILP) model, including specifying one or more variables, expressions and/or constraints thereof, to provide a solution for determining, generating and/or executing the wire-cutting, in a manner that is faster, more efficient and/or less costly than existing frameworks for determining wire-cutting or for other existing quantum circuit division frameworks (e.g., gate-cutting). For example, in one or more cases, a time for execution of a large quantum circuit (e.g., about 100 or more qubits) using an embodiment described herein can employ about 20% to about 50% fewer cuts and take only approximately 3% to approximately 10% of the execution time employed for quantum circuit execution using an existing wire-cutting method. In one or more cases, a time for execution of a small quantum circuit (e.g., about 30 or fewer qubits) using an embodiment described herein can employ about 1 or 3 fewer cuts and take only approximately 1% to approximately 10% of the execution time employed for quantum circuit execution using an existing wire-cutting method.

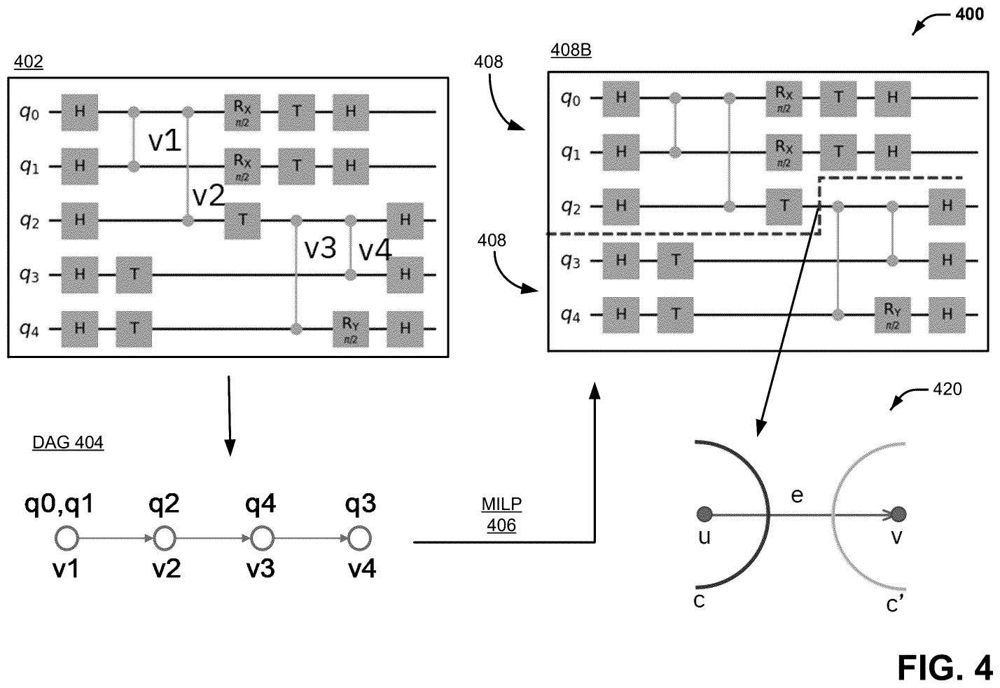

Turning now to FIG. 4, provided is a schematic 400 illustrating a base or existing wire-cutting framework, to provide a baseline for explanation of one or more embodiments for determining wire-cutting that can be executed by a system, computer-implemented method and/or computer-program product described herein. At FIG. 4, illustrated is an original quantum circuit 402 where two-qubit gates are specified by V (e.g., V1, V2, V3, V4) with vertices vᵢ, where i is a representative numeral 1, 2, 3 or 4 at the DAG. A suitable MILP model 406 can be employed to divide the original quantum circuit 402 (represented as G), using an existing wire-cutting method, into a quantity of subcircuits c (408) illustrated at quantum circuit depiction B (408B). As noted above, this existing wire-cutting method can be inefficient, and high in cost, time, number of qubits, etc.

A DAG 404, where G=(V,E) can represent the DAG 404, can be employed to represent the quantum circuit 402 and to further illustrate the existing wire cutting method. G is the quantum circuit, V is a two-qubit gate, and E is a set of edges e of two-qubit gates in the DAG, where vᵢ is a vertex of a two-qubit gate and eᵢ is an edge of the set E. The edge eᵢ represents a connection between two-qubit gates acting on at least one same qubit with a direction (from the source vertex to the destination vertex). The gate corresponding to the source vertex will be executed before the gate corresponding to the destination vertex. At DAG 404, it is noted that each vertex v belongs to a single subcircuit c or c′ and that edges e that span different subcircuits are referred to as cuts. For example, see illustration 420 at FIG. 4, showing two vertices u and v, and an edge e, where u and v belong to subcircuits c and c′, respectively, and where v is a downstream vertex that belongs to subcircuit c′, and u is an upstream vertex that belongs to subcircuit c.

Wire-cutting parameters employed by a suitable MILP model 406 and can comprise a specified number of subcircuits N_{C} to employ, where the MILP model 406 can identify and employ plural solutions N_{C} to determine an optimal final solution having a lowest cost of execution. That is, a goal of the MILP model 406 can be to minimize a total cut operation, referred to herein as a CutQC operation. CutQC can comprise execution of all quantum subcircuits and reconstruction of the entire state vector to determine a final output of the original quantum circuit.

Decision variables employed by the suitable MILP model 406 can comprise y_{v,c}=1 if vertex v is in a subcircuit c, else 0, or x_{e,c}=1 if edge e is employed for a cut by subcircuit c, else 0.

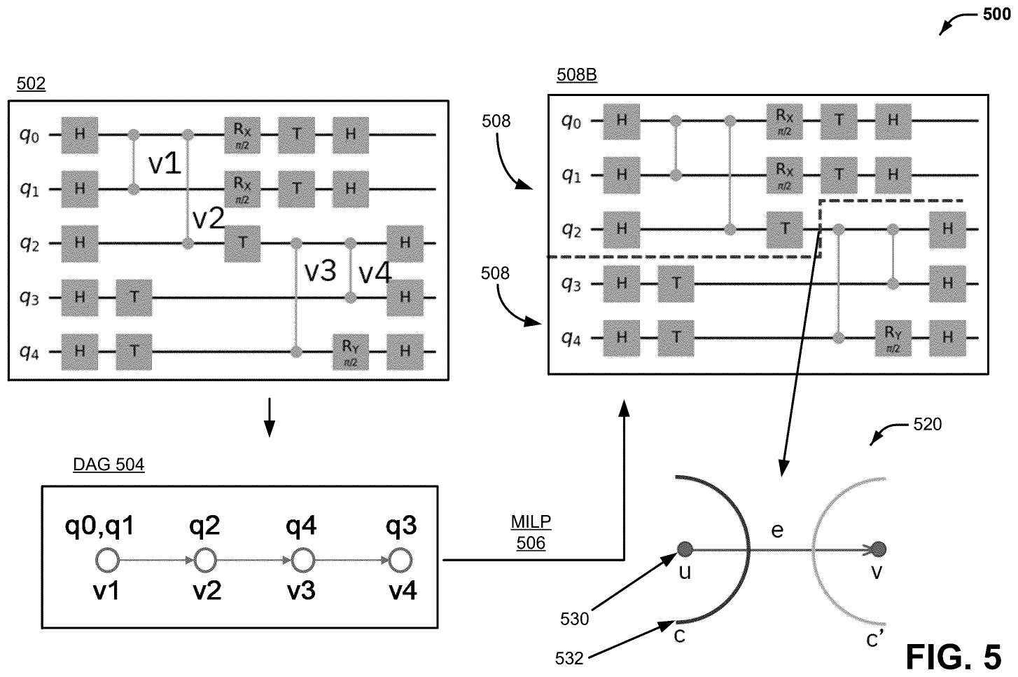

Different from the wire-cutting method of FIG. 4, a novel wire-cutting method illustrated at FIGS. 5 to 8 can provide a solution for determining, generating and/or executing the wire-cutting, in a manner that is faster, more efficient and/or less costly than existing frameworks for determining wire-cutting or for other existing quantum circuit division frameworks. As used herein, cost can refer to bandwidth, monetary cost, number of qubits, number of gates to execute, number of quantum subcircuits to execute, etc. As used herein, faster can refer to speed of determination of a wire-cutting solution and optionally, generation of a resulting two or more quantum subcircuits based on the wire-cutting solution.

For example, with reference to FIG. 5, relative to an assumption of n vertices and m edges in a DAG representing a quantum circuit (for which DAG 504 is but one example), the one or more embodiments described herein can provide for wire-cutting with only O(n N_{C}) decision variables, where N_{C} is a maximum number of subcircuits (e.g., N_{C} can be a user entity-defined parameter). Differently, an existing framework can employ O(n N_{C}+m N_{C}) decision variables. As used herein, O is the big-O notation.

It is noted that an assumption is made that an associated input graph is connected. Otherwise, the connected components can be executed independently. Thus, it holds that m>n, and more practically, m>>n.

An existing framework, generally referenced with respect to a base framework as illustrated at FIG. 4, can require one or more vertex constraints to provide for association of vertex variables and also one or more edge constraints to provide for association of edge variables. A base total number of such constraints in an existing method is O(m N_{C}), where N_{C} is the number of quantum subcircuits, n is a number of vertices, m is a number of edges in a DAG, and O is the big-O notation. For example, the total number of constraints of an exemplary existing framework (e.g., relative to FIG. 4) and the number of constraints of the one or more embodiments described herein (e.g., relative to FIG. 5) are both O(n+m N_{C}). As such, relative to FIG. 5, while an order of number of constraints may not vary, the one or more embodiments described herein do not employ constraints for association of node variables and/or edge variables.

For example, referring now to FIG. 5, provided is a schematic 500 illustrating novel wire-cutting framework for determining wire-cutting that can be executed by a system, computer-implemented method and/or computer-program product described herein. Generally, a novel wire-cutting solution can be realized, employing the one or more embodiments herein, by using fewer variables and fewer constraints than existing frameworks/methods. In this way, a MILP solver can more rapidly obtain a wire-cutting solution (e.g., comprising a number and location of wire cuts), and further, a number of wire cuts employed in the wire-cutting solution can be reduced proportionally with respect to an increase in qubits employed.

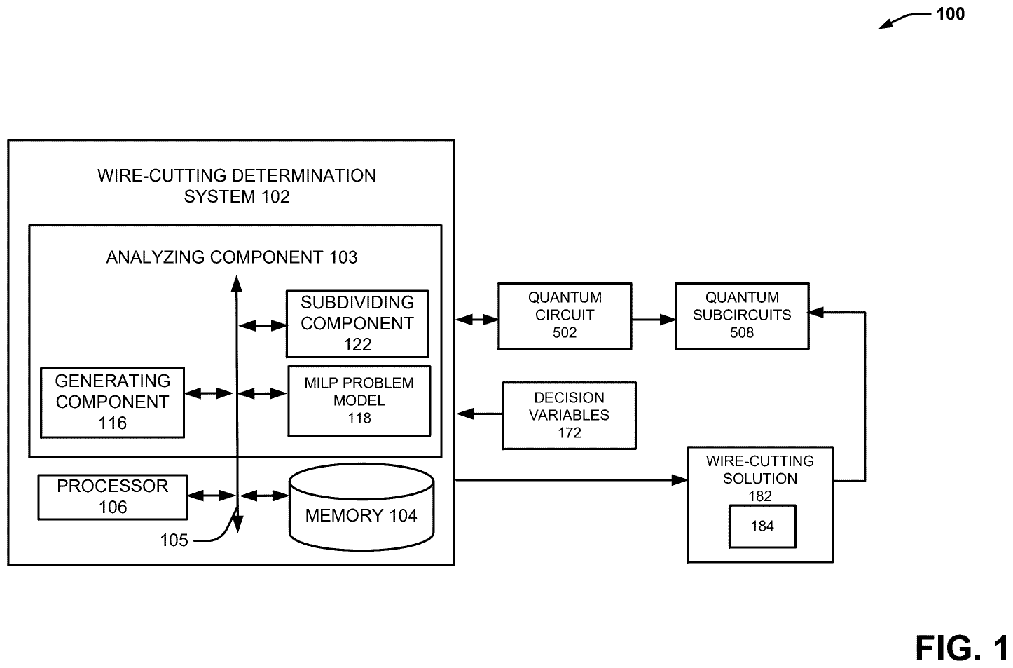

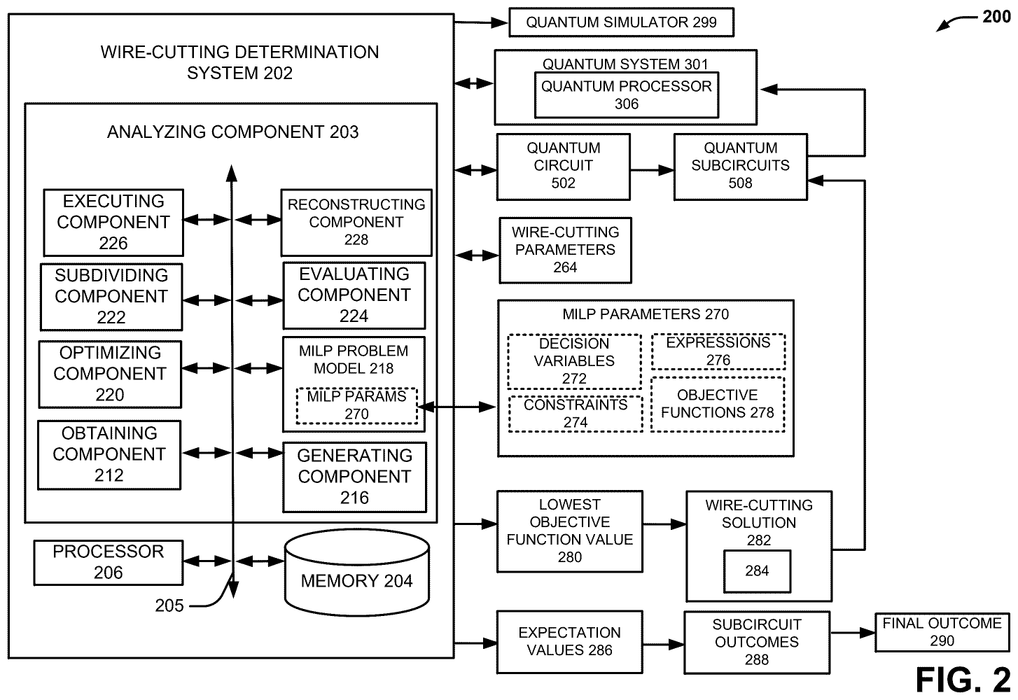

For example, illustrated at FIG. 5 is a small quantum circuit comprising use of 5 qubits, q₀ to q₄. An original quantum circuit 502 is illustrated, with two-qubit gates being specified by V (e.g., V1, V2, V3, V4) with vertices vᵢ, where i is a representative numeral 1, 2, 3 or 4 at a DAG 504. A suitable MILP model 506 can be generated and employed, by the one or more embodiments described herein, to divide the original quantum circuit 502 (represented as G), using a wire-cutting method described herein (e.g., executed by a wire-cutting determination system 102 of FIG. 1 or wire-cutting determination system 202 of FIG. 2), into a quantity of quantum subcircuits c (508) illustrated at quantum circuit depiction B (508B).

A DAG 504, where G=(V,E) can represent the DAG 504, can be employed to represent the quantum circuit 502 and to further illustrate the existing wire cutting method. G is the quantum circuit, Vis a set of two-qubit gates, and E is a set of edges of two-qubit gates in the DAG 504, where vᵢ is a vertex of a two-qubit gate and eᵢ is an edge. An objective for use of the DAG 504 can be to select edges that correspond to wire-cuts, in a manner such that the reconstruction cost can be minimized.

At DAG 504, it is noted that each vertex v belongs to a single quantum subcircuit c or c′ and that a set E of edges e span different quantum subcircuits are referred to as wire cuts. For example, see illustration 520 at FIG. 5, showing two vertices u and v, a set E of edges e, where u and v belong to subcircuits c and c′, respectively, and where v is a downstream vertex that belongs to subcircuit c′, and u is an upstream vertex that belongs to subcircuit c.

FIGS. 5-8 will be explained below in greater detail relative to one or more processes that can be performed by the non-limiting system 100 (FIG. 1) and/or non-limiting system 200 (FIG. 2).

Generally, the one or more frameworks discussed herein can comprise one or more processes comprising, but not limited to, obtaining and/or determining wire-cutting parameters, mapping a quantum circuit into a DAG of multi-qubit gates ignoring single-qubit gates, generating a MILP problem model to be employed for subdividing the quantum circuit into quantum subcircuits, applying decision variables and constraints to the MILP problem model, applying a MILP solver to optimize the MILP model, executing the MILP solver using the optimized MILP model to obtain a wire-cutting solution, and/or determining quantum subcircuits based on the wire-cutting solution.

In one or more embodiments, plural MILP problem models can be generated and/or employed, with a final wire-cutting solution from the plural MILP problem models being one having a lowest objective function value. In one or more embodiments, a lowest objective function can be based on a total number of cuts and/or simulation cost (e.g., number of sub circuits employed, execution time, maximum subcircuit width, and/or maximum subcircuit length, without being limited thereto). In one or more embodiments, a feedback loop can be employed, allowing for user entity feedback to adjust one or more MILP decision variables, MILP constraints, MILP expressions, MILP objective functions and/or wire-cutting parameters.

Using the aforementioned processes, the one or more frameworks discussed herein can provide for significant reduction of a number of variables and/or number of constraints in an optimized MILP problem model compared use of an existing framework for wire-cutting solution. Put more generally, the one or more embodiments described herein can minimize a total cut operation, referred to herein as a CutQC operation, to a level comprising less cost than existing frameworks. CutQC can comprise execution of all quantum subcircuits c and reconstruction of the entire state vector to determine a final output of the original quantum circuit. As used herein, as noted above, cost can refer to bandwidth, monetary cost, number of qubits, number of gates to execute, number of quantum subcircuits to execute, etc.

This can be enabled because the one or more frameworks described herein can provide a focus on definition of vertices 530 instead of a focus on definition of edges 532 (e.g., based on an omission of a focus on direct definition of edges 532). Rather, as noted above, definition of edges 532 can be determined instead based on the definition of the vertices 530. That is, upstream edges 532 and downstream edges 532 can instead be represented based on the decision variables 272 associated with the vertices 530.

As used herein, the term upstream refers to a source side of wire-cut edge 532 and the term downstream refers to a destination side of a wire-cut edge 532.

The one or more frameworks discussed herein can thus allow for planning of wire-cutting of a quantum circuit in a reduced time, provision of a solution of higher quality, and/or provision of a solution with a smaller reconstruction cost, as compared to use of an existing framework for wire-cutting solution. In one or more cases, the one or more embodiments described herein also can allow for planning of wire-cutting of a larger quantum circuit that can be possible with use of an existing framework for wire-cutting solution. Because the proposed optimization model requires fewer number of variables and constraints than the conventional method, the proposed method can manage a larger quantum circuit with limits of numbers of variables and constraints.

As used herein, the term “data” can comprise metadata.

As used herein, the terms “entity,” “requesting entity,” “user entity,” and “administrating entity” can refer to a machine, device, component, hardware, software, smart device, party, organization, individual and/or human.

One or more embodiments are now described with reference to the drawings, where like referenced numerals are used to refer to like elements throughout. In the following description, for purposes of explanation, numerous specific details are set forth to provide a more thorough understanding of the one or more embodiments. It is evident in various cases, however, that the one or more embodiments can be practiced without these specific details.

Further, it should be appreciated that the embodiments depicted in one or more figures described herein are for illustration only, and as such, the architecture of embodiments is not limited to the systems, devices and/or components depicted therein, nor to any particular order, connection and/or coupling of systems, devices and/or components depicted therein.

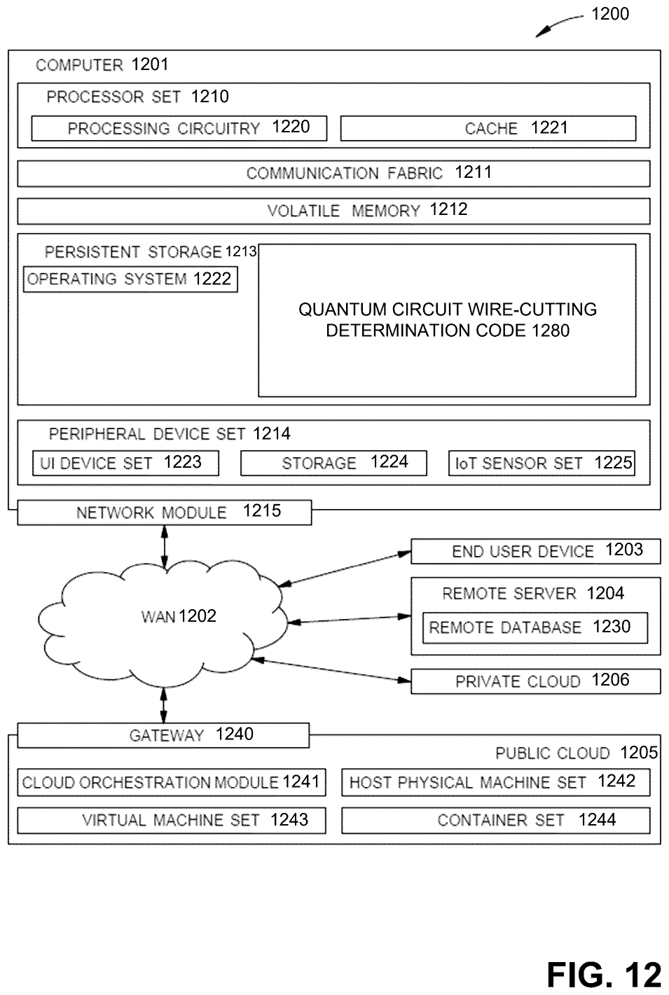

For example, in one or more embodiments, the non-limiting systems 100 and/or 200 illustrated at FIGS. 1 and 2, and/or systems thereof, can further comprise one or more computer and/or computing-based elements described herein with reference to a computing environment, such as the computing environment 1200 illustrated at FIG. 12. In one or more described embodiments, computer and/or computing-based elements can be used in connection with implementing one or more of the systems, devices, components and/or computer-implemented operations shown and/or described in connection with FIGS. 1 and/or 2 and/or with one or more other figures described herein.

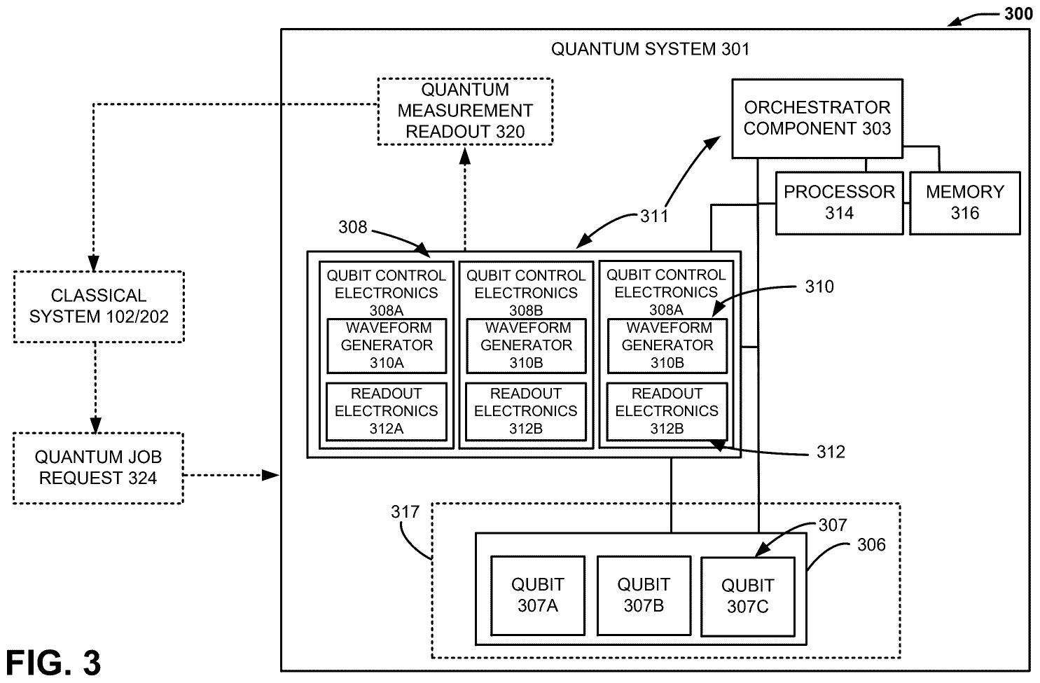

Turning now in particular to one or more figures, and first to FIG. 1, the figure illustrates a block diagram of an example, non-limiting system 100 that can provide for generation of a wire-cutting solution for subdividing a quantum circuit into a set of two or more quantum subcircuits for employment by a quantum simulator or by a quantum system 301 (FIG. 3).

That is, the non-limiting system 100 can comprise a wire-cutting determination system 102, to be described in detail below. It is noted that the wire-cutting determination system 102 is only briefly described relative to FIG. 1 to provide but a lead-in to description of a more complex and/or more expansive wire-cutting determination 202 as illustrated at FIG. 2. That is, further detail regarding processes that can be performed by one or more embodiments described herein will be provided below relative to the non-limiting system 200 of FIG. 2.

Still referring to FIG. 1, and also to FIG. 5, the wire-cutting determination system 102 can comprise at least a memory 104, bus 105, processor 106, generating component 116, MILP problem model 118, and/or subdividing component 122. Using these components, the wire-cutting determination system 102 can provide for generation of a set of quantum subcircuits 508 based on a wire-cutting solution 182 generated by the wire-cutting determination system 102 relative to a quantum circuit 502.

Generally, the generating component 116 can generate a mixed integer linear programming (MILP) problem model 118 representing a vertex 530 of quantum subcircuits 508 to be subdivided from a quantum circuit 502.

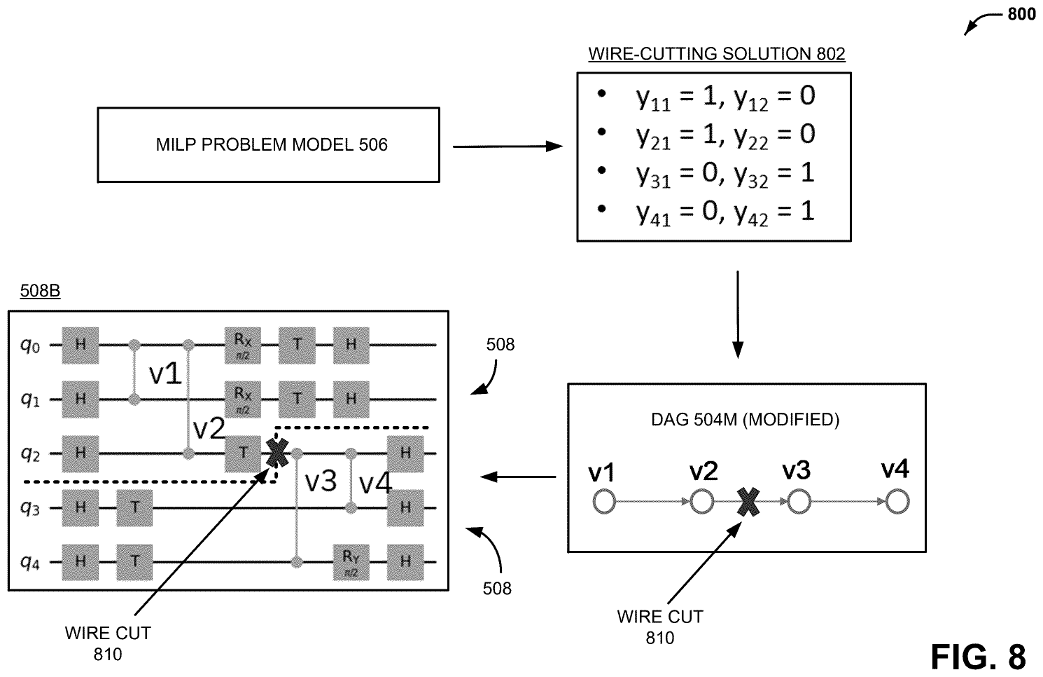

In response to the generating of the MILP problem model 118, and using the MILP problem model 118, the subdividing component 122 generally can identify a wire-cutting edge 532 based on a decision variable 172 applied by the MILP problem model 118 and corresponding to the vertex 530 and generates a wire-cutting solution 182 comprising cut data 184 defining a wire cut 810 (FIG. 8) to be applied to the quantum circuit 502 to obtain the quantum subcircuits 508.

In one or more embodiments, the generating component 116, MILP problem model 118 and/or the subdividing component 122 can be implemented independently, without the other of the generating component 116, MILP problem model 118 and/or the subdividing component 122. Additionally and/or alternatively, the generating component 116, MILP problem model 118 and/or the subdividing component 122 can be comprised by a high-level analyzing component 103, the high-level analyzing component 103 can perform one or more of the above-described functions of the generating component 116, MILP problem model 118 and/or the subdividing component 122, and/or the generating component 116, MILP problem model 118 and/or the subdividing component 122 can be omitted with the high-level analyzing component 103 performing one or more of the above-described functions of the omitted generating component 116, MILP problem model 118 and/or the subdividing component 122.

In general, the non-limiting system 100 can employ any suitable method of communication (e.g., electronic, communicative, internet, infrared, fiber, etc.) to provide communication between the classical system 102 and the quantum system 301.

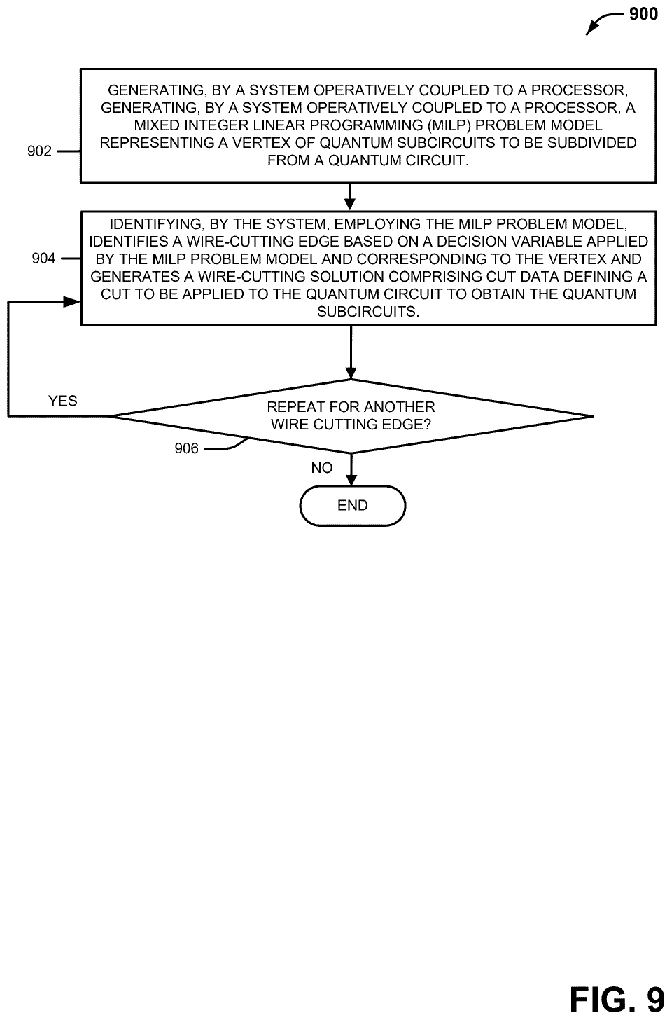

As a summary, referring next briefly to FIG. 9, illustrated is a flow diagram of an example, non-limiting method 900 that can provide a process to generate a wire-cutting solution for a quantum circuit, in accordance with one or more embodiments described herein, such as the non-limiting system 100 of FIG. 1. Repetitive description of like elements and/or processes employed in respective embodiments is omitted for sake of brevity.

At 902, the non-limiting method 900 can comprise generating, by a system operatively coupled to a processor (e.g., generating component 116 coupled to processor 106), a mixed integer linear programming (MILP) problem model (e.g., MILP problem model 118) representing a vertex (e.g., vertex 530) of quantum subcircuits (e.g., quantum subcircuits 508) to be subdivided from a quantum circuit (e.g., quantum circuit 502).

At 904, the non-limiting method 900 can comprise identifying, by the system (e.g., subdividing component 122), employing the MILP problem model, identifies a wire-cutting edge (e.g., edge 532) based on a decision variable (e.g., decision variables 172) applied by the MILP problem model and corresponding to the vertex and generates a wire-cutting solution (e.g., wire-cutting solution 182) comprising cut data (e.g., cut data 184) defining a wire cut (e.g., wire cut 810) to be applied to the quantum circuit to obtain the quantum subcircuits.

At 906, the non-limiting method 900 can comprise determining, by the system (e.g., subdividing component 122), whether to repeat the identifying for another wire-cutting edge. If yes, the non-limiting method 900 can proceed back to step 904. If not, the non-limiting method 900 can end.

Turning next to FIG. 2, a non-limiting system 200 is illustrated that can comprise a wire-cutting determination system 202. Repetitive description of like elements and/or processes employed in respective embodiments is omitted for sake of brevity. Description relative to an embodiment of FIG. 1 can be applicable to an embodiment of FIG. 2. Likewise, description relative to an embodiment of FIG. 2 can be applicable to an embodiment of FIG. 1.

Generally, the non-limiting system 200 can facilitate determination a wire-cutting solution for subdividing a quantum circuit into a set of two or more quantum subcircuits that can be operated at a quantum simulator or at a quantum system (e.g., quantum system 301 optionally comprised by the non-limiting system 200)

Turning first to the wire-cutting determination system 202, one or more communications between one or more components of the non-limiting system 200 can be provided by wired and/or wireless means including, but not limited to, employing a cellular network, a wide area network (WAN) (e.g., the Internet), and/or a local area network (LAN). Suitable wired or wireless technologies for supporting the communications can include, without being limited to, wireless fidelity (Wi-Fi), global system for mobile communications (GSM), universal mobile telecommunications system (UMTS), worldwide interoperability for microwave access (WiMAX), enhanced general packet radio service (enhanced GPRS), third generation partnership project (3GPP) long term evolution (LTE), third generation partnership project 2 (3GPP2) ultra-mobile broadband (UMB), high speed packet access (HSPA), Zigbee and other 802.XX wireless technologies and/or legacy telecommunication technologies, BLUETOOTH®, Session Initiation Protocol (SIP), ZIGBEE®, RF4CE protocol, WirelessHART protocol, 6LoWPAN (Ipv6 over Low power Wireless Area Networks), Z-Wave, an advanced and/or adaptive network technology (ANT), an ultra-wideband (UWB) standard protocol and/or other proprietary and/or non-proprietary communication protocols.

The wire-cutting determination system 202 can be associated with, such as accessible via, a cloud computing environment.

The wire-cutting determination system 202 can comprise a plurality of components. The components can comprise a memory 204, processor 206, bus 205, obtaining component 212, generating component 216, MILP problem model 218, optimizing component 220, subdividing component 222, evaluating component 224, executing component 226, and/or reconstructing component 228. Using these components, and particularly employing the MILP problem model 218, the non-limiting system 200 generally can provide one or more wire-cutting solutions 282 that can be employed, by the one or more embodiments, to determine one or more expectation values 286, which in turn can be employed, by the one or more embodiments, to determine an outcome 288 of the quantum circuit 502.

That is, the obtaining component 212, generating component 216, MILP problem model 218, optimizing component 220, subdividing component 222, evaluating component 224, executing component 226, and/or reconstructing component 228 can operate at the classical system 202 of the non-limiting system 200. One or more quantum circuits (e.g., quantum circuits 504 and/or quantum subcircuits 508) can be executed by the quantum system 301. In one or more other embodiments, one or more processes performed by any one or more of the obtaining component 212, generating component 216, MILP problem model 218, optimizing component 220, subdividing component 222, evaluating component 224, executing component 226, and/or reconstructing component 228 can be performed at the quantum system 301.

Discussion first turns briefly to the processor 206, memory 204 and bus 205 of the wire-cutting determination system 202. For example, in one or more embodiments, the wire-cutting determination system 202 can comprise the processor 206 (e.g., computer processing unit, microprocessor, classical processor, quantum processor and/or like processor). In one or more embodiments, a component associated with wire-cutting determination system 202, as described herein with or without reference to the one or more figures of the one or more embodiments, can comprise one or more computer and/or machine readable, writable and/or executable components and/or instructions that can be executed by processor 206 to provide performance of one or more processes defined by such component and/or instruction. In one or more embodiments, the processor 206 can comprise the obtaining component 212, generating component 216, MILP problem model 218, optimizing component 220, subdividing component 222, evaluating component 224, executing component 226, and/or reconstructing component 228.

In one or more embodiments, the wire-cutting determination system 202 can comprise the computer-readable memory 204 that can be operably connected to the processor 206. The memory 204 can store computer-executable instructions that, upon execution by the processor 206, can cause the processor 206 and/or one or more other components of the wire-cutting determination system 202 (e.g., obtaining component 212, generating component 216, MILP problem model 218, optimizing component 220, subdividing component 222, evaluating component 224, executing component 226, and/or reconstructing component 228) to perform one or more actions. In one or more embodiments, the memory 204 can store computer-executable components (e.g., obtaining component 212, generating component 216, MILP problem model 218, optimizing component 220, subdividing component 222, evaluating component 224, executing component 226, and/or reconstructing component 228).

The wire-cutting determination system 202 and/or a component thereof as described herein, can be communicatively, electrically, operatively, optically and/or otherwise coupled to one another via a bus 205. Bus 205 can comprise one or more of a memory bus, memory controller, peripheral bus, external bus, local bus, quantum bus and/or another type of bus that can employ one or more bus architectures. One or more of these examples of bus 205 can be employed.

In one or more embodiments, the wire-cutting determination system 202 can be coupled (e.g., communicatively, electrically, operatively, optically and/or like function) to one or more external systems (e.g., a non-illustrated electrical output production system, one or more output targets and/or an output target controller), sources and/or devices (e.g., classical and/or quantum computing devices, communication devices and/or like devices), such as via a network. In one or more embodiments, one or more of the components of the wire-cutting determination system 202 and/or of the non-limiting system 200 can reside in the cloud, and/or can reside locally in a local computing environment (e.g., at a specified location).

In general, the non-limiting system 200 can employ any suitable method of communication (e.g., electronic, communicative, internet, infrared, fiber, etc.) to provide communication between the wire-cutting determination system 202 and the quantum system 301.

In addition to the processor 206 and/or memory 204 described above, the wire-cutting determination system 202 can comprise one or more computer and/or machine readable, writable and/or executable components and/or instructions that, when executed by processor 206, can provide performance of one or more operations defined by such component and/or instruction.

Discussion next turns to the additional components of the wire-cutting determination system 202 (e.g., obtaining component 212, generating component 216, MILP problem model 218, optimizing component 220, subdividing component 222, evaluating component 224, executing component 226, and/or reconstructing component 228).

First, it is noted that in one or more embodiments, the obtaining component 212, generating component 216, MILP problem model 218, optimizing component 220, subdividing component 222, evaluating component 224, executing component 226, and/or reconstructing component 228 can be implemented independently, without one or more other of the obtaining component 212, generating component 216, MILP problem model 218, optimizing component 220, subdividing component 222, evaluating component 224, executing component 226, and/or reconstructing component 228. Additionally and/or alternatively, the obtaining component 212, generating component 216, MILP problem model 218, optimizing component 220, subdividing component 222, evaluating component 224, executing component 226, and/or reconstructing component 228 can be comprised by a high-level analyzing component 203, one or more of the below-described functions of the obtaining component 212, generating component 216, MILP problem model 218, optimizing component 220, subdividing component 222, evaluating component 224, executing component 226, and/or reconstructing component 228 can be performed by the high-level analyzing component 203, and/or the obtaining component 212, generating component 216, MILP problem model 218, optimizing component 220, subdividing component 222, evaluating component 224, executing component 226, and/or reconstructing component 228 can be omitted with the high-level analyzing component 203 performing one or more of the below-described functions of the one or more omitted obtaining component 212, generating component 216, MILP problem model 218, optimizing component 220, subdividing component 222, evaluating component 224, executing component 226, and/or reconstructing component 228.

Discussion now turns to FIGS. 5-8 illustrating one or more processes that can be performed by the wire-cutting determination system 202, and also still to FIG. 2.

Referring first to the obtaining component 212, the obtaining component 212 generally can find, locate, determine, request, download, read and/or otherwise obtain information (e.g., data and/or metadata) relating to a request for quantum circuit execution and/or a request for wire-cutting determination relative to a quantum circuit 502. For example, relative to a request for execution of a quantum circuit 502, the obtaining component 212 can compare a number of qubits to be employed for the quantum circuit 502 to a number of qubits employable at a quantum system (e.g., quantum system 301) or quantum simulator for executing the quantum circuit 502. Based upon the comparison, if the number of qubits to be employed for the quantum circuit 502 is larger than allowable by the quantum simulator or quantum system, the obtaining component 212 can generate a request to the wire-cutting determination system 202 to automatically determine a wire-cutting solution 282 for generating set of two or more quantum subcircuits 508 from the quantum circuit 502. That is, the quantum subcircuits 508 can have reduced numbers of qubits to be employed for their individual executions as compared to the quantum circuit 502. In this way, it can be possible to employ the available quantum system or quantum simulator to execute the quantum circuit 502.

Likewise, the obtaining component 212 can find, locate, determine, request, download, read and/or otherwise obtain information (e.g., data and/or metadata) relating to wire-cutting parameters 264 to be employed for generating a MILP problem model 218 by the wire-cutting determination system 202. In one or more embodiments, such wire-cutting parameters 264 can comprise, but are not limited to a maximum number of wire cuts (also herein referred to as cuts), maximum number of subcircuits, maximum subcircuit length, maximum subcircuit width, and/or maximum wire-cutting solving time. Likewise, the obtaining component 212 can find, locate, determine, request, download, read and/or otherwise obtain information (e.g., data and/or metadata) relating to MILP parameters 270 to be employed by a generated MILP problem model 218. In one or more embodiments, such MILP parameters 270 can comprise one or more decision variables 272 and/or one or more constraints 274, to be discussed below relative to the MILP problem model 218.

As used herein, circuit length can refer to number of gates executed at a qubit (e.g., at one wire of a quantum circuit illustration). As used herein, circuit width can refer to number of qubits employed (e.g., number of wires of a quantum circuit illustration).

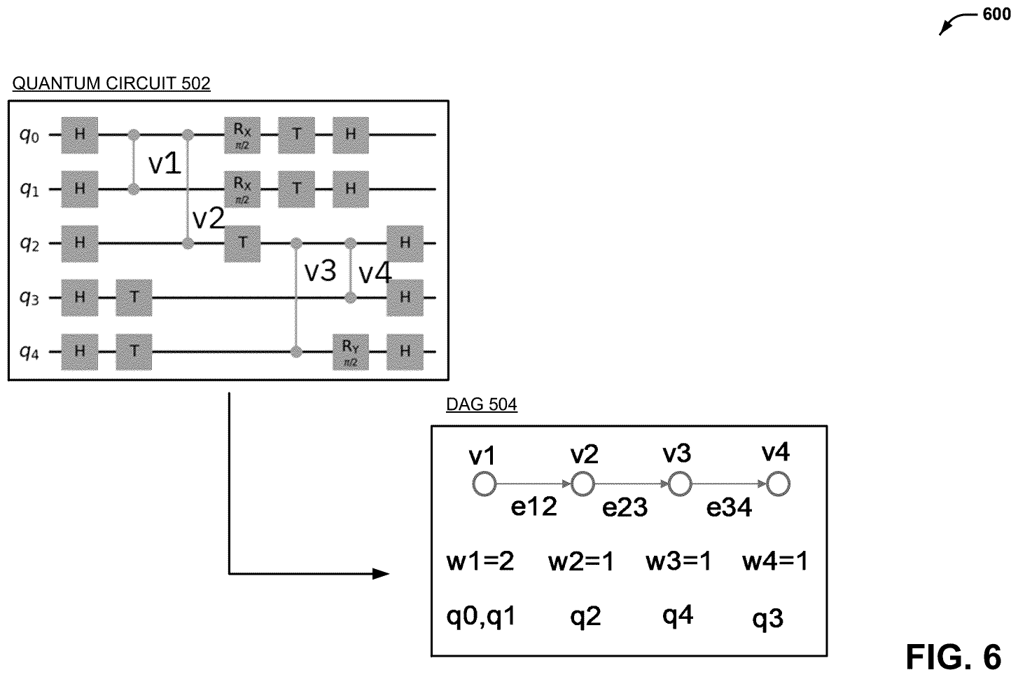

Looking now to partial schematic flow diagram 600 of FIG. 6, upon identifying a request to execute wire-cutting, the generating component 216 can initiate a generation of a directed acyclic graph (DAG) 504. It is noted that such generation need not necessarily product a visual or viewable DAG 504. Rather, generation of a DAG 504 can be in data format only, such as employed by a computing device, processor 206, etc. Such DAG 504, as previously described, can comprise a directed graph with no cycles, used to represent the quantum circuit 502. The DAG 504 is generated without single-qubit gates (e.g., the generation ignores single-qubit gates of the quantum circuit 502).

For example, illustrated at FIG. 6 is a small quantum circuit 502 comprising use of 5 qubits, q₀ to q₄. This original quantum circuit 502 is illustrated with two-qubit gates (e.g., CZ, CNOT, etc.) being specified by V (e.g., V1, V2, V3, V4) with vertices vᵢ, where i is 1, 2, 3 or 4 at the DAG 504. The DAG 504, where G=(V,E) can represent the DAG 504, can be employed to represent the quantum circuit 502 and to further illustrate the existing wire cutting method. G is the quantum circuit graph based on V and E, where V is a two-qubit gate, and E is a set of edges e of two-qubit gates in the DAG 504, where vᵢ is a vertex of a two-qubit gate and eᵢ is an edge connecting vertices whose two-qubit gates act on at least one of the same qubits. The gate corresponding to the source vertex of the edge eᵢ will be executed before that corresponding to the destination vertex of the edge eᵢ. At DAG 504, it is noted that each vertex v belongs to a single subcircuit c and that edges e that span different subcircuits are referred to as cuts. For example, see illustration 520 at FIG. 5, showing two vertices u and v, and edge e.

Also at the DAG 506, W is a set of initialization qubits (e.g., |0>) directly connected to vᵢ, where wᵢ represents a particular initialization qubit. It is noted that w₂=1 because v₂ is connected to q₀ and q₂, but v₁ exists between q₀ and v₂. W can be derived by traversing vertices (i.e., two-qubit gates) of G in the topological ordering and counting the number of connected initialization qubits that are not used by other two-qubit gates before.

Additionally, and/or alternatively, upon identifying a request to execute wire-cutting, the generating component 216 can initiate a generation of a MILP problem model 218 to be subsequently optimized (e.g., by the optimizing component 220) and/or operated upon by a MILP solver (e.g., subdividing component 222) to determine a number of wire cuts 810 and/or one or more locations of such wire cuts 810 at the quantum circuit 502.

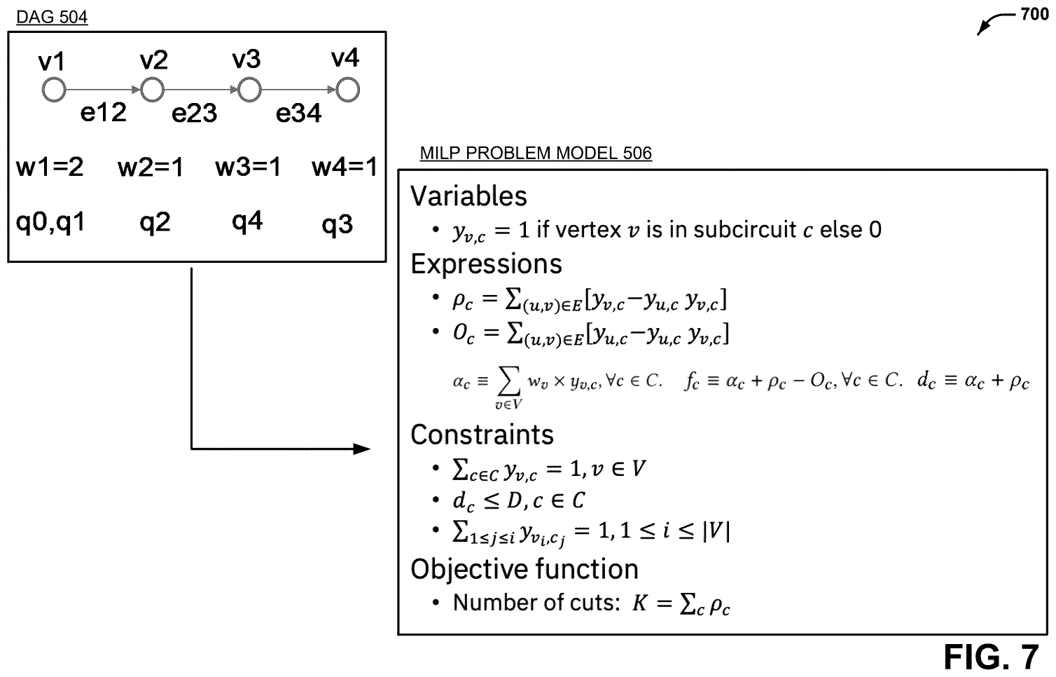

Discussion turns first to generation of the MILP problem model 218 and to the partial schematic flow diagram 700 of FIG. 7.

To generate the MILP problem model 218, the generating component 216 can obtain the wire-cutting parameters 264 obtained by the obtaining component 212. In one or more embodiments, relative to the quantum circuit 502, herein also referred to as G, the wire-cutting parameters 264 sought by the generating component 216 (e.g., as specified by default and/or by a user entity) can comprise a maximum number of subcircuits to employ (e.g., N_{C}) and a maximum number of qubits per subcircuit to employ (e.g., D). For example, in the exemplary flow charts of FIGS. 5-8, N_{C}=2 and D=3. In one or more embodiments, the MILP problem model 218 can be generated to operate relative to an option of more than one N_{C}, thus trying one or more such N_{C} during its execution. Addition of one or more other wire-cutting parameters 264 as noted above (maximum subcircuit length, maximum subcircuit width, and/or maximum wire-cutting solving time) can be optional. It is noted that addition of one or more additional wire-cutting parameters 264 can lengthen an execution time of the wire-cutting processes to wire-cutting solution 282, as performed by the wire-cutting determination system 202.

Identification of which wire-cutting parameters 264 to employ can be based on historical data accessible to the generating component 216 and/or based on input data provided by a user entity (e.g., using a device communicatively couplable to the non-limiting system 200). In the case of historical data, the generating component 216 can employ those wire-cutting parameters 264 that correspond to historical wire-cutting parameters corresponding to a historical quantum circuit execution for which the historical wire-cutting parameters were same and/or similar to the wire-cutting parameters 264. In an example, a threshold can be employed, such as where a number of wire-cutting parameters 264 or more is to be the same for a historical quantum circuit as the quantum circuit 502 and/or where a specified historical wire-cutting parameter is within a specified value (e.g., x) of a wire-cutting parameter 264 corresponding to the quantum circuit 502.

To generate the MILP problem model 218, the generating component 216 can determine and/or generate one or more MILP parameters 270. These MILP parameters 270 can comprise, without being limited thereto, decision variables 272, constraints 274, expressions 276 and/or objective functions 278.

The generating component 216 can determine an objective function 278 to employ upon which the MILP problem model 218 can be based. For example, the objective function 278 can be a first objective function based upon reconstruction cost corresponding to the quantum subcircuits 508. A first objective function can be represented by K=Σ_{c}ρ_{c}, where c is a subcircuit. With respect to this expression, a number of downstream vertices in subcircuit c can be represented by ρ_{c}=Σ_{(u,v)∈E}[y_{v,c}−y_{u,c} y_{v,c}], where v is a vertex of the input DAG, e is an edge of the input DAG, and y_{v,c} and similar are variables defined for all vertices v and subcircuits c. That is, y_{v,c} and similar are are binary variables (can be 0 or 1) defined for all vertices v and subcircuits c.

As used herein, reconstruction cost can refer to the aggregation of the outcomes 288 of execution of the quantum subcircuits 508 to thereby realize a final outcome of the original quantum circuit 502. Methods for reconstruction are not discussed herein and are known to those having ordinary skill in the art.

For another example, the objective function 278 can be a second objective function based upon both the reconstruction cost corresponding to the quantum subcircuits 508 and a simulation cost associated with execution of the quantum subcircuits 508 at a quantum computing simulator. A second objective function can be represented by 2K+Σ_{c}f_{c}, where c is a subcircuit and f_{c} is defined below. It is noted that the second objective function can approximate an original cost function as a linear function. An original cost function can be represented by

$$L ≡ {4}^{K} {\sum }_{c = 2}^{{n}_{C}} {\prod }_{i = 1}^{c} {2}^{{f}_{i}} .$$

In one or more embodiments, the first objective function can be employed as a default and/or when the generating component 216 does not identify data in the initial request specifying execution at a quantum simulator. The second objective function can be employed when the generating component 216 identifies data in the initial request specifying execution of the quantum circuit 502 at a quantum simulator.

Notably, when generating the MILP problem model 218, the generating component 216 can employ one or more decision variables 272 relative to vertices 530 to be determined using the MILP problem model 218, but not decision variables relative to edges 532 to be also determined using the MILP problem model 218. That is, decision variables relative to the edges 532 omitted. Put another way, using the MILP parameters 270, the MILP problem model 218 can identify a wire-cutting edge 532 based on a decision variable 272 relative to a vertex 530. This reduction in use of decision variables (e.g., not including decision variables relative to wire-cutting edges 532) can significantly reduce complexity of the MILP problem model 218 and time to generate a wire-cutting solution 282 using the MILP problem model 218.

In one or more embodiments, a decision variable 272 can define metes and bounds of the MILP problem model 218. In one or more embodiments, the decision variables 272 can be defined for all vertices v and subcircuits c=(1, . . . , N_{c}). This set of decision variables 272 can be referred to as an array of decision variables 272. A decision variable 272 can include y_{v,c}=1 if vertex v is in subcircuit c else 0. This decision variable 272 can represent whether each individual vertex 530 is in each quantum subcircuit c determined by the MILP problem model 218.

Identification of which decision variables 272 to employ can be based on historical data accessible to the generating component 216 and/or based on input data provided by a user entity (e.g., using a device communicatively couplable to the non-limiting system 200). In the case of historical data, the generating component 216 can employ those decision variables 272 that correspond to historical decision variables corresponding to a historical quantum circuit execution for which the historical wire-cutting parameters were same and/or similar to the wire-cutting parameters 264. In an example, a threshold can be employed, such as where a number of wire-cutting parameters 264 or more is to be the same for a historical quantum circuit as the quantum circuit 502 and/or where a specified historical wire-cutting parameter is within a specified value (e.g., x) of a wire-cutting parameter 264 corresponding to the quantum circuit 502.

In one or more embodiments, the generating component 216 can employ one or more expressions 276 to define metes and bounds of the MILP problem model 218. This can include y_{u,c} y_{v,c} where y_{u,c} y_{v,c}=1 if and only if (iff) both u and v belong to subcircuit c.

Another expression 276 can be edge e=(u,v) is a wire cut, u and v are determined as upstream vertex and downstream vertex, respectively. Another expression 276 can be (u, v) is a wire cut and v is a downstream vertex that belongs to subcircuit c iff y_{v,c}−y_{u,c} y_{v,c}=1. With respect to this expression, a number of downstream vertices in subcircuit c can be represented by ρ_{c}=Σ_{(u,v)∈E}[y_{v,c}−y_{u,c} y_{v,c}], where v is a vertex of the input DAG, e is an edge of the input DAG, and y_{v,c} and similar are variables defined for all vertices v and subcircuits c.

Another expression 276 can be (u, v) is a wire cut and u is an upstream vertex that belongs to subcircuit c iff y_{u,c}−y_{u,c} y_{v,c}=1. With respect to this expression, a number of upstream vertices in subcircuit c can be represented by O_{c}=Σ_{(u,v)∈E}[y_{u,c}−y_{u,c} y_{v,c}], where edge (u, v) is a cut and u belongs to subcircuit c (upstream).

A number of initialization qubits directly connected to subcircuit c can be specified as α_{c}. Number of qubits of subcircuit c that contributes to the entire execution cost can be specified as f_{c}. Number of qubits of subcircuit c that is constrained to be within the number of qubits of a device to execute the quantum circuits can be specified as d_{c}. With respect thereto, the following expressions can be employed:

$${α}_{c} ≡ {\sum }_{v ∈ V} {w}_{v} \times {y}_{v , c} , ∀ c ∈ C .$$

$${f}_{c} ≡ {α}_{c} + {ρ}_{c} - {O}_{c} , ∀ c ∈ C .$$

$${d}_{c} ≡ {α}_{c} + {ρ}_{c} .$$

Note that variables in these expressions are expanded, e.g., d_{c}<=D is transformed to α_{c}+ρ_{c}<=D. Then Σ_{{v∈V}}[wᵥ y_{v,c}]+Σ_{(u,v)∈E}[y_{v,c}−y_{u,c} y_{v,c}]=D (due to definitions of α_{c} and ρ_{c}).

Identification of which expressions 276 to employ can be based on historical data accessible to the generating component 216 and/or based on input data provided by a user entity (e.g., using a device communicatively couplable to the non-limiting system 200). In the case of historical data, the generating component 216 can employ those expressions 276 that correspond to historical expressions corresponding to a historical quantum circuit execution for which the historical wire-cutting parameters were same and/or similar to the wire-cutting parameters 264. In an example, a threshold can be employed, such as where a number of wire-cutting parameters 264 or more is to be the same for a historical quantum circuit as the quantum circuit 502 and/or where a specified historical wire-cutting parameter is within a specified value (e.g., x) of a wire-cutting parameter 264 corresponding to the quantum circuit 502.

In one or more embodiments, the generating component 216 can employ one or more constraints 274 to define metes and bounds of the MILP problem model 218. This includes Σ_{c∈C}y_{v,c}=1, v∈V; d_{c}≤D, c∈C; and Σ_{1≤j≤i}yᵥ_{_{i,}}_{c}_{ⱼ}=1, 1≤i≤|V|, which breaks symmetry by enforcing vᵢ belongs to either c₁, . . . , cᵢ.

In on one or more embodiments, constraints 274 can comprise using a technique to represent a product of binary variables with a set of linear constraints. This can include replacing y_{u,c} y_{v,c} with binary variable z_{u,v,c} and employing the following transformed constraints: z_{u,v,c}≤y_{u,c}, z_{u,v,c}≤y_{v,c}, and z_{u,v,c}≥y_{u,c}+y_{v,c}−1. That is, the constraints 274 can be transformed into Σ_{v∈V}[wᵥ y_{v,c}]+Σ_{(u,v)∈E}[y_{v,c}−z_{u,v,c}]<=D, with the transformed constraints being appended to the MILP problem model 218 by the generating component 216.

In one or more embodiments, one or more constraints 274 can specify and/or cause that no single vertex 530 is assigned to plural quantum subcircuits 508. In one or more embodiments, one or more constraints 274 can specify and/or cause that the size of all quantum subcircuits 508 is less than or equal to D (e.g., the specified maximum size any single quantum subcircuit).

Identification of which constraints 274 to employ can be based on historical data accessible to the generating component 216 and/or based on input data provided by a user entity (e.g., using a device communicatively couplable to the non-limiting system 200). In the case of historical data, the generating component 216 can employ those constraints 274 that correspond to historical constraints corresponding to a historical quantum circuit execution for which the historical wire-cutting parameters were same and/or similar to the wire-cutting parameters 264. In an example, a threshold can be employed, such as where a number of wire-cutting parameters 264 or more is to be the same for a historical quantum circuit as the quantum circuit 502 and/or where a specified historical wire-cutting parameter is within a specified value (e.g., x) of a wire-cutting parameter 264 corresponding to the quantum circuit 502.

As noted above, in one or more embodiments, the generating component 216 can employ fewer decision variables 272 and/or fewer constraints 274 than are employed by existing frameworks for determining wire-cutting solutions. This can be enabled because the one or more frameworks described herein can provide a focus on definition of vertices 530 instead of a focus on definition of edges 532. Rather, as noted above, definition of edges 532 can be determined instead based on the definition of the vertices 530. That is, upstream edges 532 and downstream edges 532 can instead be represented based on the decision variables 272 associated with the vertices 530.

In summary, upon determination of the various MILP parameters 270 and/or wire-cutting parameters 264, the generating component 216 can generate an associated objective function by combining the MILP parameters 270 and expanding the associated variables in the expressions 276, resulting in the MILP problem model 218. In one or more embodiments, the generating component 216 can generate the MILP problem model 218 to comprise any suitable number of layers, nodes, vectors, and/or the like.

Based on generation of the MILP problem model 218, the optimizing component 220 can perform one or more optimizations of the MILP problem model 218. In one or more embodiments, the optimizing component 220 can be, comprise and/or employ a suitable solver. As used herein, a solver can be an executable program that can read a problem interactively and/or from files in certain standard formats, solve the problem, and/or deliver the solution interactively and/or into one or more text files.

Discussion next turns to the partial schematic flow diagram 800 of FIG. 8. The subdividing component 222, employing the MILP problem model 218 output by the optimizing component 220, can generate a wire-cutting solution 282. The MILP problem model 218 determines the optimal solution, e.g., the values of all variables y_{v,c}. Then, the subdividing component 222 can identify a wire-cut if y_{v,c}−y_{u,c}y_{v,c}=1 for some edge e=(u, v) and subcircuit c, e.g., by checking all combinations of edge e and subcircuit c.

As a further part of this process, the subdividing component 222 can identify a set of one or more wire cuts 810, referred to as e=(u, v), such that y_{v,c}−y_{u,c}y_{v,c}=1 for each subcircuit c in the modified DAG 504. As noted above, y_{v,c} generally represents a binary variable assigned to DAG vertex v and subcircuit c. For example, if y₃₂−y₂₂ y₃₂=1 holds, edge (v2, v3) is a wire cut 810. For another example, y₁₂=0 refers to decision variable y₁₂ takes 0. That is, y_{v,c} with v=1, c=2, means that vertex 1 does not belong to sub circuit 2. For another example, y_{1,1}=1 means that the variable y_{1,1} takes 1 in the optimal solution. Since there are 4 DAG nodes and 2 subcircuits at DAG 504, v can be 1, 2, 3, or 4, and c can be 1 or 2.

A wire-cutting solution 282 can comprise cut data 284 defining one or more wire cuts 810. A wire cut 810 can be a location along a virtual qubit wire where the quantum circuit 502 can be split into the quantum subcircuits 508. Put another way, a wire cut 810 can be a specified break between quantum gates of a quantum circuit. As noted above, at wire-cutting solution 282, y_{v,c}=0 means DAG vertex v does not belong to subcircuit c, and y_{v,c}=1 means DAG vertex v belongs to subcircuit c.

In one or more embodiments, the MILP model 406 can determine plural solutions for plural wire-cutting parameters N_{C}. A wire-cutting solution can be associated with and generated by the MILP model 406 for two or more of such wire-cutting parameters N_{C}. In such case, a wire-cutting solution having a lowest objective function value, as specified by the MILP model 406, can be employed as the final wire-cutting solution 282 having the cut data 284 to be employed for determining where to apply one or more wire cuts 810.

Using the cut data 284 of the wire-cutting solution 282, the subdividing component 222 can determine where to apply the one or more wire cuts 810 (specified by the cut data 284) with respect to data defining the quantum circuit 502. For example, the subdividing component 222 can generate a marker, tag or other metadata corresponding to a wire cut 810, which marker, tag or other metadata can be directly and/or indirectly applied to data defining the quantum circuit 502. Based thereon, the subdividing component 222 can generate two or more quantum subcircuits 508 from the quantum circuit 502.

In one or more embodiments, and still to FIG. 8, in one or more embodiments, a modified DAG 504M can be generated by the subdividing component 222, such as by applying cut data 284 of the wire-cutting solution 282 to the DAG 504. For example, the marker, tag or other metadata can be applied to the DAG 504, to represent the wire cut 810, thus resulting in a modified DAG 504M. In such case, a location of a wire cut 810 can be generated, such as a location visually illustrated at modified DAG 504M at FIG. 8.

Accordingly, based on any final output of the wire-cutting solution 282, a plurality of quantum subcircuits 508 can be determined by the subdividing component 222. For example, the subdividing component 222 can rewrite the quantum circuit 504 into the plurality of corresponding quantum subcircuits 508 using the cut data 284. Accordingly, the subdividing component 222 can generate a set of quantum circuits being a set of two or more quantum subcircuits 508. For example, the subdividing component 222 can read data corresponding to the quantum subcircuit 502. The data can have a marker applied thereto (e.g., directly and/or by reference), where the marker can correspond to a wire cut 810. The marker can thereby represent a stop action (e.g., indicating stopping reading of the data for the current quantum subcircuit being generated) or a start actin (e.g., indicating to start reading the data for a next quantum subcircuit).

In one or more embodiments, the wire-cutting determination system 202 can allow for feedback-based modification of the wire-cutting solution 282. That is, the evaluating component 224 can request and/or obtain feedback from a user entity, such as having digital access to the wire-cutting determination system 202 by use of a suitable computing device having communicative access to the wire-cutting determination system 202. Based on the feedback, the evaluating component 224 can request modification by the subdividing component 222 of the wire-cutting solution 282. In one or more cases, the feedback can comprise request to employ a particular wire-cutting parameter N_{c}, and/or to employ a particular objective function 278, decision variable 272, constraint 274 and/or expression 276. In one or more cases, the feedback can comprise request to employ a particular location for a wire cut 810, number of quantum subcircuits, depth of quantum subcircuits, etc. That is, although these aspects can be specified ahead of time, e.g., before generation of, or in correspondence with generation of, the MILP problem model 218 by the generating component 216, review of the wire-cutting solution 282 by a user entity can result in an altered decision, logic, view, determination, etc. by the user entity.

Based on the quantum subcircuits 508 resulting from the subdividing component 222, in one or more embodiments, the executing component 226 can generate a quantum job request 324 (FIG. 3) comprising data defining execution of one or more of the quantum subcircuits 508 at a quantum system or quantum simulator, which quantum job request 324 can be employed by the quantum system (e.g., quantum system 301) or quantum simulator to execute the plurality of quantum subcircuits 508 to return quantum measurement readouts 320.

Next, prior to discussion of use of the quantum measurement readouts 320 that can be employed to determine one or more expectation values 286 corresponding to the quantum subcircuits 508, discussion first turns to a general description of an exemplary quantum system 301 that can be employed to provide execution of the quantum subcircuits 508 (e.g., which are themselves quantum circuits) in connection with the classical system 202.

Turning next to FIG. 3, one or more embodiments described herein can include one or more devices, systems and/or apparatuses that can provide a process to generate one or more waveforms or pulses for a quantum-based operation (e.g., using a quantum device), such as for operating one or more qubits of a quantum device. Accordingly, at FIG. 3, illustrated is a block diagram of an example, non-limiting system 300 that can at least partially facilitate such a process. While referring here to one or more processes, facilitations and/or uses of the non-limiting system 300, description provided herein, both above and below, also can be relevant to one or more other non-limiting systems described herein, such as the non-limiting systems 100 and/or 200.

As illustrated at FIG. 3, the non-limiting system 300 can comprise a quantum system 301 that can be employed with or separate from the classical systems 102/202.

Generally, the quantum system 301 (e.g., quantum computer system, superconducting quantum computer system and/or the like) can employ quantum algorithms and/or quantum circuitry, including computing components and/or devices, to perform quantum operations and/or functions on input data to produce results that can be output to an entity. The quantum circuitry can comprise quantum bits (qubits), such as multi-bit qubits, physical circuit level components, high level components and/or functions. The quantum circuity can comprise physical pulses that can be structured (e.g., arranged and/or designed) to perform desired quantum functions and/or computations on data (e.g., input data and/or intermediate data derived from input data) to produce one or more quantum results as an output. The quantum results, e.g., quantum measurement readout 320, can be responsive to a quantum job request 324 and associated input data, which can be based at least in part on the input data, quantum functions and/or quantum computations (e.g., here comprising data defining one or more quantum subcircuits 508).

In one or more embodiments, the quantum system 301 can comprise components, such as an orchestrator component 303, a quantum processor 306, pulse component (e.g., a waveform generator 310) and/or a readout electronics 312 (e.g., readout component).

The quantum processor 306 can comprise one or more, such as plural, qubits 307. Individual qubits 307A, 307B and 307C, for example, can be fixed frequency and/or single junction qubits, such as transmon qubits.

In one or more embodiments, a readout resonator can be associated with, such as located with physical hardware defining a qubit 307.

In one or more embodiments, a memory 316 and/or processor 314 can be associated with the orchestrator component 303, where suitable. The processor 314 can be any suitable processor. The processor 314 can generate one or more instructions for controlling the one or more processes of the orchestrator component 303, such as for controlling one or more subordinate controllers (e.g., qubit control electronics 308).

The orchestrator component 303 can obtain (e.g., download, receive, search for and/or the like) a quantum job request 324 requesting execution of one or more quantum programs and/or a physical qubit layout. The quantum job request 324 can be provided in any suitable format, such as a text format, binary format and/or another suitable format. In one or more embodiments, the quantum job request 324 can be obtained by a component other than of the quantum system 301, such as a by a component of the classical systems 102/202.

The orchestrator component 303 can determine mapping of one or more quantum logic circuits for executing a quantum program. In one or more embodiments, the orchestrator component 303 and/or quantum processor 306 can direct the waveform generator 310 to generate one or more pulses, tones, waveforms and/or the like to affect one or more qubits 307, such as in response to a quantum job request 324.

In one or more embodiments, more than one orchestrator component 303 can be comprised by the quantum system 301. The one or more orchestrator components 303 can be employed to control one or more qubit control electronics 308. Thus, the one or more qubit control electronics 308A, 308B and/or 308C can be communicatively coupled to the one or more orchestrator components 303.

Qubit control electronics 308 can be employed by the quantum processor 306 and disposed within a room temperature environment external to the cryogenic environment 317, as illustrated. In one or more embodiments, one or more aspects of one or more qubit control electronics can be disposed within a cryogenic environment 317.

In one or more embodiments a qubit control electronics 308 can be provided per qubit 307. In one or more embodiments, a qubit control electronics 308 can be provided to communicate with more than one qubit 307 per that qubit control electronics 308.

In one or more embodiments, a qubit control electronics 308 can be and/or can comprise a qubit drive card (e.g., a waveform generator 310) and/or a qubit acquire card (e.g., readout electronics 312). In one or more embodiments, a qubit control electronics 308 can be and/or can comprise only one of a qubit drive card or a qubit acquire card. In one or more embodiments, a qubit control electronics 308 can comprise more than one qubit drive card and/or more than one qubit acquire card.

A waveform generator 310 generally can cause at least one qubit 307 of the quantum processor 306 to perform one or more quantum processes, calculations and/or measurements by creating a suitable electro-magnetic signal. For example, the waveform generator 310 can operate one or more qubit effectors, such as qubit oscillators, harmonic oscillators, pulse generators and/or the like to cause one or more pulses to stimulate and/or manipulate the state(s) of the one or more qubits 307 comprised by the quantum system 301. Indeed, a signal can be generated by the waveform generator 310 to affect one or more of the plurality of qubits 307.

In one or more embodiments, the waveform generator 310 can direct application of such electro-magnetic signal by use of the various qubit control electronics 308.

The quantum processor 306 can be contained in a cryogenic environment, such as generated by a cryogenic environment 317, such as effected by a dilution refrigerator. Where the plurality of qubits 307 are superconducting qubits, cryogenic temperatures, such as about 4K or lower, can be employed for function of these physical qubits.

The readout electronics 312 can comprise and/or be comprised by the acquire card. The readout electronics 312 and/or the acquire card can comprise an analog to digital converter (ADC) 315 that can be employed for the readout path of one or more qubits 307. The readout electronics 312, or at least a portion thereof, can be contained in a room temperature environment or the cryogenic environment 317, such as for reading a state, frequency and/or other characteristic of qubit, excited, decaying or otherwise. Accordingly, one or more elements of the readout electronics 312 also can be constructed to perform at such cryogenic temperatures.

In one or more embodiments, more than one cryogenic environment, such as more than one dilution refrigerator, can be comprised by the quantum system 301.

It is noted that one or more aspects of the aforementioned description can refer to operation of a single set of instructions run on a single qubit controller or set of qubit control electronics. However, scaling can be achieved. For example, instructions can be calculated, transmitted, employed and/or otherwise used relative to one or more qubits (e.g., non-neighbor qubits) in parallel with one another, one or more quantum circuits in parallel with one another, and/or one or more qubit mappings in parallel with one another.

Turning now back to FIG. 2, in addition to still referring to FIG. 3, discussion turns to one or more additional processes that can be performed by one or more additional components of the wire-cutting determination system 202.

Based on the quantum measurement readouts 320 output by the quantum system 301 or output by a suitable quantum simulator, the reconstructing component 228 can determine one or more expectation values 286 and subcircuit outcomes 288. That is, for any particular quantum subcircuit 508, execution thereof can be performed plural times, allowing for determination of an expectation value 286 based on the respective measurement readouts 320 from the plural executions thereof. For example, an expectation value 286 can represent a probability or determination associated with a particular measurable qubit state.

Based on the expectation values 286, the reconstructing component 228 can determine plural outcome 288 for the different quantum subcircuits 508 and can reconstruct a final outcome 290 associated with the original quantum circuit 502 (e.g., based on suitable methods for reconstruction known by one having ordinary skill in the art). As used herein, the term reconstruction can refer to consolidation of the subcircuit outcomes 288 to obtain the final outcome 290. It is noted that such a reconstruction cost associated with such reconstruction can be directly reduced by the one or more embodiments described herein, as compared to a reconstruction cost associated with existing frameworks, by minimization of a number of wire cuts 810 as output by the MILP problem model 218.

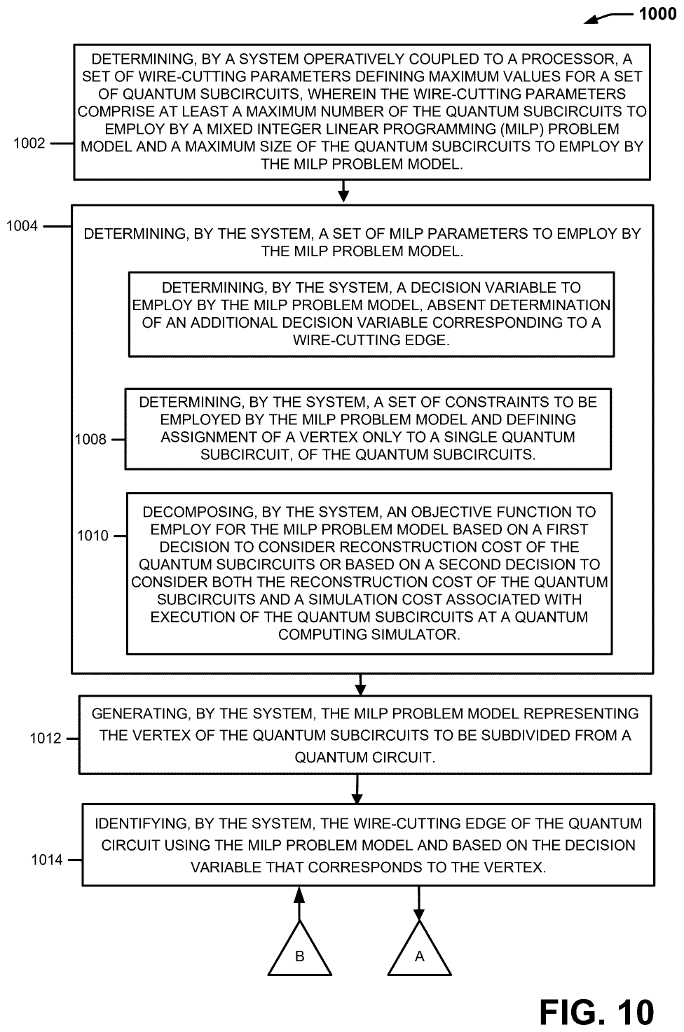

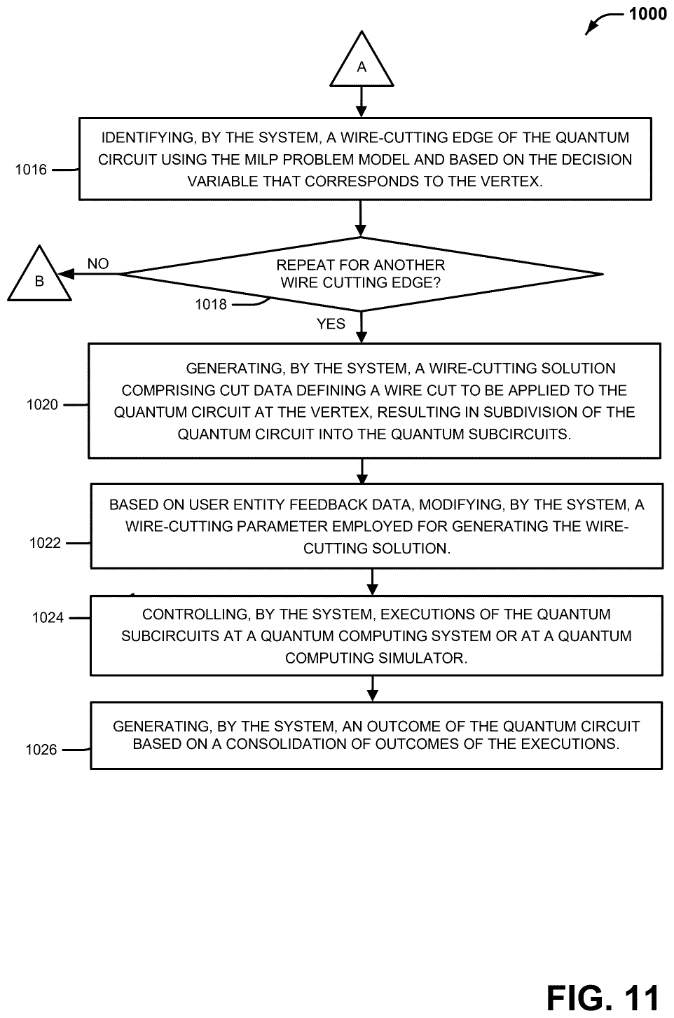

As a summary, referring next to FIGS. 10 and 11, illustrated is a flow diagram of an example, non-limiting method 1000 that can provide a process to determine a wire-cutting solution 282 for a quantum circuit 508, in accordance with one or more embodiments described herein, such as the non-limiting system 200 of FIG. 2. While the non-limiting method 1000 is described relative to the non-limiting system 200 of FIG. 2, the non-limiting method 1000 can be applicable also to other systems described herein, such as the non-limiting system 100 of FIG. 1. Repetitive description of like elements and/or processes employed in respective embodiments is omitted for sake of brevity.

At 1002, the non-limiting method 1000 can comprise determining, by a system operatively coupled to a processor (e.g., generating component 214), a set of wire-cutting parameters (e.g., wire-cutting parameters 264) defining maximum values for a set of quantum subcircuits (e.g., quantum subcircuits 508), wherein the wire-cutting parameters comprise at least a maximum number of the quantum subcircuits to employ by a mixed integer linear programming (MILP) problem model (e.g., MILP problem model 218) and a maximum size of the quantum subcircuits to employ by the MILP problem model.

At 1004, the non-limiting method 1000 can comprise determining, by the system (e.g., generating component 214), a set of MILP parameters (e.g., MILP parameters 270) to employ by the MILP problem model.

At 1006, step 1004 can comprise determining, by the system (e.g., generating component 214), a decision variable (e.g., decision variable 272) to employ by the MILP problem model, absent determination of an additional decision variable corresponding to a wire-cutting edge (e.g., edge 532).

At 1008, step 1004 can comprise determining, by the system (e.g., generating component 214), a set of constraints (e.g., constraints 274) to be employed by the MILP problem model and defining assignment of a vertex (e.g., vertex 530) only to a single quantum subcircuit, of the quantum subcircuits.

At 1010, step 1004 can comprise determining, by the system (e.g., generating component 214), an objective function (e.g., objective function 278) to employ for the MILP problem model based on a first decision to consider reconstruction cost of the quantum subcircuits or based on a second decision to consider both the reconstruction cost of the quantum subcircuits and a simulation cost associated with execution of the quantum subcircuits at a quantum computing simulator.

At 1012, the non-limiting method 1000 can comprise generating, by the system (e.g., generating component 214), the MILP problem model representing the vertex of the quantum subcircuits to be subdivided from a quantum circuit (e.g., quantum circuit 502).

At 1014, the non-limiting method 1000 can comprise identifying, by the system (e.g., subdividing component 222), the wire-cutting edge of the quantum circuit using the MILP problem model and based on the decision variable that corresponds to the vertex.

At 1016, the non-limiting method 1000 can comprise determining, by the system (e.g., subdividing component 222), a number of wire-cutting edges, including the wire-cutting edge, as being equal to a number of vertices represented by the MILP problem model, including the vertex.

At 1018, the non-limiting method 1000 can comprise determining, by the system (e.g., subdividing component 222), whether to repeat the identifying for another wire-cutting edge. If yes, the non-limiting method 1000 can proceed back to step 1014. If not, the non-limiting method can proceed to step 1020.

At 1020, the non-limiting method 1000 can comprise generating, by the system (e.g., subdividing component 222), a wire-cutting solution (e.g., wire-cutting solution 282) comprising cut data (e.g., cut data 284) defining a wire cut (e.g., wire cut 810) to be applied to the quantum circuit at the vertex, resulting in subdivision of the quantum circuit into the quantum subcircuits.

At 1022, the non-limiting method 1000 can comprise based on user entity feedback data, modifying, by the system (e.g., evaluating component 224), a wire-cutting parameter employed for generating the wire-cutting solution.

At 1024, the non-limiting method 1000 can comprise controlling, by the system (e.g., executing component 226), executions of the quantum subcircuits at a quantum computing system (e.g., quantum computing system 301) or at a quantum computing simulator (e.g., quantum computing simulator (299).

At 1026, the non-limiting method 1000 can comprise generating, by the system (e.g., reconstructing component 228), an outcome (e.g., final outcome 290) of the quantum circuit based on a consolidation of outcomes (e.g., subcircuit outcomes 288) of the executions.

### Additional Summary

For simplicity of explanation, the computer-implemented and non-computer-implemented methodologies provided herein are depicted and/or described as a series of acts. It is to be understood that the subject innovation is not limited by the acts illustrated and/or by the order of acts, for example acts can occur in one or more orders and/or concurrently, and with other acts not presented and described herein. Furthermore, not all illustrated acts can be utilized to implement the computer-implemented and non-computer-implemented methodologies in accordance with the described subject matter. In addition, the computer-implemented and non-computer-implemented methodologies could alternatively be represented as a series of interrelated states via a state diagram or events. Additionally, the computer-implemented methodologies described hereinafter and throughout this specification are capable of being stored on an article of manufacture for transporting and transferring the computer-implemented methodologies to computers. The term article of manufacture, as used herein, is intended to encompass a computer program accessible from any computer-readable device or storage media.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

In summary, the one or more embodiments described herein can provide a system, computer-implemented method and/or computer program product to determine wire-cutting solution 282 for subdividing a quantum circuit 502 into a set of two or more quantum subcircuits 508 for being more easily executed at a quantum simulator and/or quantum system (e.g., quantum system 301). A system 100, 200 comprises a memory 104, 204 that stores computer executable components, and a processor 106, 206 that executes the computer executable components stored in the memory 104, 204, wherein the computer executable components comprise a generating component 116, 216, that generates a mixed integer linear programming (MILP) problem model 118, 218 representing a vertex 530 of quantum subcircuits 508 to be subdivided from a quantum circuit 502, and a subdividing component 122, 222 that, identifies a wire-cutting edge 532 of the quantum circuit 502 using the MILP problem model 118, 218 and based on a decision variable 172, 272 that corresponds to the vertex 530.

A benefit of the system, computer-implemented method and/or computer program product can be an ability to, plan wire-cutting of quantum circuits much faster than via use of an existing framework. With respect to use of a quantum simulation, the one or more embodiments described herein can be employed to generate a wire-cutting solution for use in simulating a quantum circuit with about 30 or more qubits, or even more than about 100 qubits using wire-cutting and state vector simulation. Indeed, while a state vector simulator cannot directly simulate such as quantum circuit directly due to memory size (e.g., requiring an O(2ⁿ) space for n-qubit system with a state-vector-based simulator), wire-cutting executed by the one or more embodiments described herein can subdivide the quantum circuit into plural quantum subcircuits with tractable sizes. It is noted that O(4^{k}) time can be required to reconstruct results of execution of the quantum subcircuits where k is the number of cuts. For example, such benefit can be applicable to use in analyzing very large unknown molecules, for example in a chemistry-related, mining-related and/or materials-related context.

That is, the one or more embodiments described herein can automatically generate a computer-based problem model (e.g., MILP problem model), digitally interact with such computer-based problem model, and/or generate quantum circuits for large quantities of qubits. Indeed, in view of the one or more embodiments described herein, a practical application of the one or more systems, computer-implemented methods and/or computer program products described herein can be an increased efficiency and/or speed of determination of a wire-cutting solution by a classical system, thereby reducing time to provision of a quantum outcome (e.g., outcome 288), by providing a framework employing reduced errors and/or reduced assumptions taken (e.g., without use of decision variables relative to edges of a DAG).

In one or more cases, the one or more embodiments can provide various degrees of scaling of the aforementioned processes. For example,

In connection therewith, the one or more embodiments described herein can provide useful and practical applications of computers, thus providing enhanced (e.g., improved and/or optimized) quantum system setup as compared to existing frameworks for determining wire-cutting solutions. Overall, such computerized tools can constitute a concrete and tangible technical improvement in the field of quantum processing.

The systems and/or devices have been (and/or will be further) described herein with respect to interaction between one or more components. Such systems and/or components can include those components or sub-components specified therein, one or more of the specified components and/or sub-components, and/or additional components. Sub-components can be implemented as components communicatively coupled to other components rather than included within parent components. One or more components and/or sub-components can be combined into a single component providing aggregate functionality. The components can interact with one or more other components not specifically described herein for the sake of brevity, but known by those of skill in the art.

One or more embodiments described herein can be, in one or more embodiments, inherently and/or inextricably tied to computer technology and cannot be implemented outside of a computing environment. For example, one or more processes performed by one or more embodiments described herein can more efficiently, and even more feasibly, provide program and/or program instruction execution, such as relative to determination of a a wire-cutting solution for subdividing a quantum circuit into set of two or more quantum subcircuits, as compared to existing systems and/or techniques unable to provide such efficiencies. Systems, computer-implemented methods and/or computer program products providing performance of these processes are of great utility in the fields of quantum computing, and optionally chemical analysis, and cannot be equally practicably implemented in a sensible way outside of a computing environment.

One or more embodiments described herein can employ hardware and/or software to solve problems that are highly technical, that are not abstract, and that cannot be performed as a set of mental acts by a human. For example, a human, or even thousands of humans, cannot efficiently, accurately and/or effectively automatically or even partially automatically perform quantum circuit execution at a plurality of qubits of a quantum system as the one or more embodiments described herein can provide these processes. Further, a human, or even thousands of humans, cannot efficiently, accurately and/or effectively automatically or even partially automatically generate a computer-based problem model (e.g., MILP problem model), digitally interact with such computer-based problem model, and/or generate quantum circuits for large quantities of qubits as the one or more embodiments described herein can provide these processes. Moreover, neither can the human mind nor a human with pen and paper conduct these processes, as conducted by one or more embodiments described herein.

In one or more embodiments, one or more of the processes described herein can be performed by one or more specialized computers (e.g., a specialized processing unit, a specialized classical computer, a specialized quantum computer, a specialized hybrid classical/quantum system and/or another type of specialized computer) to execute defined tasks related to the one or more technologies describe above. One or more embodiments described herein and/or components thereof can be employed to solve new problems that arise through advancements in technologies mentioned above, employment of quantum computing systems, cloud computing systems, computer architecture and/or another technology.

One or more embodiments described herein can be fully operational towards performing one or more other functions (e.g., fully powered on, fully executed and/or another function) while also performing one or more of the one or more operations described herein.

To provide additional summary, a listing of embodiments and features thereof is provided.

A system, comprising: a memory that stores computer executable components; and a processor, operably coupled to the memory, that executes the computer executable components stored in the memory, wherein the computer executable components comprise: a generating component that generates a mixed integer linear programming (MILP) problem model representing a vertex of quantum subcircuits to be subdivided from a quantum circuit; and a subdividing component that identifies a wire-cutting edge of the quantum circuit using the MILP problem model and based on a decision variable that corresponds to the vertex.

The system of the preceding paragraph, wherein the subdividing component generates a wire-cutting solution comprising cut data defining a wire cut to be applied to the quantum circuit at the vertex, resulting in subdivision of the quantum circuit into the quantum subcircuits.

The system of the preceding paragraph, wherein the generating component determines a set of MILP parameters comprising the decision variable absent determination of an additional decision variable corresponding to the wire-cutting edge.

The system of any preceding paragraph, wherein the generating component determines a set of constraints to be employed by the MILP problem model and defining assignment of the vertex only to a single quantum subcircuit, of the quantum subcircuits.

The system of any preceding paragraph, wherein the generating component determines a set of wire-cutting parameters defining maximum values for the quantum subcircuits, wherein the wire-cutting parameters comprise at least a maximum number of the quantum subcircuits to employ by the MILP problem model and a maximum size of the quantum subcircuits to employ by the MILP problem model.

The system of any preceding paragraph, wherein the subdividing component determines a number of wire-cutting edges, including the wire-cutting edge, as being equal to a number of vertices represented by the MILP problem model, including the vertex.

The system of any preceding paragraph, wherein the generating component determines an objective function to employ for the MILP problem model based on a first decision to consider reconstruction cost of the quantum subcircuits or based on a second decision to consider both the reconstruction cost of the quantum subcircuits and a simulation cost associated with execution of the quantum subcircuits at a quantum computing simulator.

The system of any preceding paragraph, wherein the computer executable components further comprise: an evaluating component that, based on user entity feedback data, modifies a wire-cutting parameter employed for generating the wire-cutting solution.

The system of any preceding paragraph, wherein the computer executable components further comprise: an executing component that controls executions of the quantum subcircuits at a quantum computing system or at a quantum computing simulator; and a reconstructing component that generates an outcome of the quantum circuit based on a consolidation of outcomes of the executions.

A computer-implemented method, comprising: generating, by a system operatively coupled to a processor, a mixed integer linear programming (MILP) problem model representing a vertex of quantum subcircuits to be subdivided from a quantum circuit; and identifying, by the system, a wire-cutting edge of the quantum circuit using the MILP problem model and based on a decision variable that corresponds to the vertex.

The computer-implemented method of the preceding paragraph, further comprising: generating, by the system, a wire-cutting solution comprising cut data defining a wire cut to be applied to the quantum circuit at the vertex, resulting in subdivision of the quantum circuit into the quantum subcircuits.

The computer-implemented method of any preceding paragraph, further comprising: determining, by the system, a set of MILP parameters comprising the decision variable absent determination of an additional decision variable corresponding to the wire-cutting edge.

The computer-implemented method of any preceding paragraph, further comprising: prior to the execution, determining, by the system, determines a set of constraints to be employed by the MILP problem model and defining assignment of the vertex only to a single quantum subcircuit, of the quantum subcircuits.

The computer-implemented method of any preceding paragraph, further comprising: determining, by the system, a set of wire-cutting parameters defining maximum values for the quantum subcircuits, wherein the wire-cutting parameters comprise at least a maximum number of the quantum subcircuits to employ by the MILP problem model and a maximum size of the quantum subcircuits to employ by the MILP problem model.

The computer-implemented method of any preceding paragraph, further comprising: determining, by the system, a number of wire-cutting edges, including the wire-cutting edge, as being equal to a number of vertices represented by the MILP problem model, including the vertex.

The computer-implemented method of any preceding paragraph, further comprising: determining, by the system, an objective function to employ for the MILP problem model based on a first decision to consider reconstruction cost of the quantum subcircuits or based on a second decision to consider both the reconstruction cost of the quantum subcircuits and a simulation cost associated with execution of the quantum subcircuits at a quantum computing simulator.

The computer-implemented method of any preceding paragraph, further comprising: based on user entity feedback data, modifying, by the system, a wire-cutting parameter employed for generating the wire-cutting solution.

The computer-implemented method of any preceding paragraph, further comprising: controlling, by the system, executions of the quantum subcircuits at a quantum computing system or at a quantum computing simulator; and determining, by the system, an outcome of the quantum circuit based on a consolidation of outcomes of the executions.

A computer program product facilitating a process to determine a quantum circuit wire-cutting solution, the computer program product comprising a computer readable storage medium having program instructions embodied therewith, the program instructions executable by a processor to cause the processor to: generate, by the processor, a mixed integer linear programming (MILP) problem model representing a vertex of quantum subcircuits to be subdivided from a quantum circuit; and identify, by the processor, a wire-cutting edge of the quantum circuit using the MILP problem model and based on a decision variable that corresponds to the vertex.

The computer program product of the preceding paragraph, wherein the program instructions are further executable by the processor to cause the processor to: determine, by the processor, a set of MILP parameters comprising the decision variable absent determination of an additional decision variable corresponding to the wire-cutting edge.

The computer program product of any preceding paragraph, wherein the program instructions are further executable by the processor to cause the processor to: determine, by the processor, a set of constraints to be employed by the MILP problem model and defining assignment of the vertex only to a single quantum subcircuit, of the quantum subcircuits.

The computer program product of any preceding paragraph, wherein the program instructions are further executable by the processor to cause the processor to: determine, by the processor, a number of wire-cutting edges, including the wire-cutting edge, as being equal to a number of vertices represented by the MILP problem model, including the vertex.

### Computing Environment Description

Turning next to FIG. 12, a detailed description is provided of additional context for the one or more embodiments described herein at FIGS. 1-11.

FIG. 12 and the following discussion are intended to provide a brief, general description of a suitable computing environment 1200 in which one or more embodiments described herein at FIGS. 1-11 can be implemented. For example, various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include diskette, hard disk, random access memory (RAM), read-only memory (ROM), crasable programmable read-only memory (EPROM or Flash memory), static random-access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Computing environment 1200 contains an example of an environment for the execution of at least some of the computer code involved in performing the inventive methods, such as translation of an original source code based on a configuration of a quantum circuit wire-cutting determination code 1280. In addition to block 1280, computing environment 1200 includes, for example, computer 1201, wide area network (WAN) 1202, end user device (EUD) 1203, remote server 1204, public cloud 1205, and private cloud 1206. In this embodiment, computer 1201 includes processor set 1210 (including processing circuitry 1220 and cache 1221), communication fabric 1211, volatile memory 1212, persistent storage 1213 (including operating system 1222 and block 1280, as identified above), peripheral device set 1214 (including user interface (UI), device sct 1223, storage 1224, and Internet of Things (IoT) sensor set 1225), and network module 1215. Remote server 1204 includes remote database 1230. Public cloud 1205 includes gateway 1240, cloud orchestration module 1241, host physical machine set 1242, virtual machine set 1243, and container set 1244.

COMPUTER 1201 may take the form of a desktop computer, laptop computer, tablet computer, smart phone, smart watch or other wearable computer, mainframe computer, quantum system or any other form of computer or mobile device now known or to be developed in the future that is capable of running a program, accessing a network or querying a database, such as remote database 1230. As is well understood in the art of computer technology, and depending upon the technology, performance of a computer-implemented method may be distributed among multiple computers and/or between multiple locations. On the other hand, in this presentation of computing environment 1200, detailed discussion is focused on a single computer, specifically computer 1201, to keep the presentation as simple as possible. Computer 1201 may be located in a cloud, even though it is not shown in a cloud in FIG. 12. On the other hand, computer 1201 is not required to be in a cloud except to any extent as may be affirmatively indicated.

PROCESSOR SET 1210 includes one, or more, computer processors of any type now known or to be developed in the future. Processing circuitry 1220 may be distributed over multiple packages, for example, multiple, coordinated integrated circuit chips. Processing circuitry 1220 may implement multiple processor threads and/or multiple processor cores. Cache 1221 is memory that is located in the processor chip package and is typically used for data or code that should be available for rapid access by the threads or cores running on processor set 1210. Cache memories are typically organized into multiple levels depending upon relative proximity to the processing circuitry. Alternatively, some, or all, of the cache for the processor set may be located “off chip.” In some computing environments, processor set 1210 may be designed for working with qubits and performing quantum computing.

Computer readable program instructions are typically loaded onto computer 1201 to cause a series of operational steps to be performed by processor set 1210 of computer 1201 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 1221 and the other storage media discussed below. The program instructions, and associated data, are accessed by processor set 1210 to control and direct performance of the inventive methods. In computing environment 1200, one or more instructions for performing the inventive methods may be stored in block 1280 in persistent storage 1213.

COMMUNICATION FABRIC 1211 is the signal conduction path that allows the various components of computer 1201 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

VOLATILE MEMORY 1212 is any type of volatile memory now known or to be developed in the future. Examples include dynamic type random access memory (RAM) or static type RAM. Typically, the volatile memory is characterized by random access, but this is not required unless affirmatively indicated. In computer 1201, the volatile memory 1212 is located in a single package and is internal to computer 1201, but, alternatively or additionally, the volatile memory may be distributed over multiple packages and/or located externally with respect to computer 1201.

PERSISTENT STORAGE 1213 is any form of non-volatile storage for computers that is now known or to be developed in the future. The non-volatility of this storage means that the stored data is maintained regardless of whether power is being supplied to computer 1201 and/or directly to persistent storage 1213. Persistent storage 1213 may be a read only memory (ROM), but typically at least a portion of the persistent storage allows writing of data, deletion of data and re-writing of data. Some familiar forms of persistent storage include magnetic disks and solid-state storage devices. Operating system 1222 may take several forms, such as various known proprietary operating systems or open-source Portable Operating System Interface type operating systems that employ a kernel. The code included in block 1280 typically includes at least some of the computer code involved in performing the inventive methods.

PERIPHERAL DEVICE SET 1214 includes the set of peripheral devices of computer 1201. Data communication connections between the peripheral devices and the other components of computer 1201 may be implemented in various ways, such as Bluetooth connections, Near-Field Communication (NFC) connections, connections made by cables (such as universal serial bus (USB) type cables), insertion type connections (for example, secure digital (SD) card), connections made though local area communication networks and even connections made through wide area networks such as the internet. In various embodiments, UI device set 1223 may include components such as a display screen, speaker, microphone, wearable devices (such as goggles and smart watches), keyboard, mouse, printer, touchpad, game controllers, and haptic devices. Storage 1224 is external storage, such as an external hard drive, or insertable storage, such as an SD card. Storage 1224 may be persistent and/or volatile. In some embodiments, storage 1224 may take the form of a quantum computing storage device for storing data in the form of qubits. In embodiments where computer 1201 is required to have a large amount of storage (for example, where computer 1201 locally stores and manages a large database) then this storage may be provided by peripheral storage devices designed for storing large amounts of data, such as a storage area network (SAN) that is shared by multiple, geographically distributed computers. IoT sensor set 1225 is made up of sensors that can be used in Internet of Things applications. For example, one sensor may be a thermometer and another sensor may be a motion detector.

NETWORK MODULE 1215 is the collection of computer software, hardware, and firmware that allows computer 1201 to communicate with other computers through WAN 1202. Network module 1215 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 1215 are performed on the same physical hardware device. In other embodiments (for example, embodiments that utilize software-defined networking (SDN)), the control functions and the forwarding functions of network module 1215 are performed on physically separate devices, such that the control functions manage several different network hardware devices. Computer readable program instructions for performing the inventive methods can typically be downloaded to computer 1201 from an external computer or external storage device through a network adapter card or network interface included in network module 1215.

WAN 1202 is any wide area network (for example, the internet) capable of communicating computer data over non-local distances by any technology for communicating computer data, now known or to be developed in the future. In some embodiments, the WAN may be replaced and/or supplemented by local area networks (LANs) designed to communicate data between devices located in a local area, such as a Wi-Fi network. The WAN and/or LANs typically include computer hardware such as copper transmission cables, optical transmission fibers, wireless transmission, routers, firewalls, switches, gateway computers and edge servers.

END USER DEVICE (EUD) 1203 is any computer system that is used and controlled by an end user (for example, a customer of an enterprise that operates computer 1201) and may take any of the forms discussed above in connection with computer 1201. EUD 1203 typically receives helpful and useful data from the operations of computer 1201. For example, in a hypothetical case where computer 1201 is designed to provide a recommendation to an end user, this recommendation would typically be communicated from network module 1215 of computer 1201 through WAN 1202 to EUD 1203. In this way, EUD 1203 can display, or otherwise present, the recommendation to an end user. In some embodiments, EUD 1203 may be a client device, such as thin client, heavy client, mainframe computer, desktop computer and so on.

REMOTE SERVER 1204 is any computer system that serves at least some data and/or functionality to computer 1201. Remote server 1204 may be controlled and used by the same entity that operates computer 1201. Remote server 1204 represents the machine that collects and stores helpful and useful data for use by other computers, such as computer 1201. For example, in a hypothetical case where computer 1201 is designed and programmed to provide a recommendation based on historical data, then this historical data may be provided to computer 1201 from remote database 1230 of remote server 1204.

PUBLIC CLOUD 1205 is any computer system available for use by multiple entities that provides on-demand availability of computer system resources and/or other computer capabilities, especially data storage (cloud storage) and computing power, without direct active management by the scale. The direct and active management of the computing resources of public cloud 1205 is performed by the computer hardware and/or software of cloud orchestration module 1241. The computing resources provided by public cloud 1205 are typically implemented by virtual computing environments that run on various computers making up the computers of host physical machine set 1242, which is the universe of physical computers in and/or available to public cloud 1205. The virtual computing environments (VCEs) typically take the form of virtual machines from virtual machine set 1243 and/or containers from container set 1244. It is understood that these VCEs may be stored as images and may be transferred among and between the various physical machine hosts, either as images or after instantiation of the VCE. Cloud orchestration module 1241 manages the transfer and storage of images, deploys new instantiations of VCEs and manages active instantiations of VCE deployments. Gateway 1240 is the collection of computer software, hardware, and firmware that allows public cloud 1205 to communicate via WAN 1202.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

PRIVATE CLOUD 1206 is similar to public cloud 1205, except that the computing resources are only available for use by a single enterprise. While private cloud 1206 is depicted as being in communication with WAN 1202, in other embodiments a private cloud may be disconnected from the internet entirely and only accessible through a local/private network. A hybrid cloud is a composition of multiple clouds of different types (for example, private, community or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 1205 and private cloud 1206 are both part of a larger hybrid cloud.

### Additional Closing Information

The embodiments described herein can be directed to one or more of a system, a method, an apparatus and/or a computer program product at any possible technical detail level of integration. The computer program product can include a computer readable storage medium (or media) having computer readable program instructions thereon for causing a processor to carry out aspects of the one or more embodiments described herein. The computer readable storage medium can be a tangible device that can retain and store instructions for use by an instruction execution device. The computer readable storage medium can be, for example, but is not limited to, an electronic storage device, a magnetic storage device, an optical storage device, an electromagnetic storage device, a superconducting storage device and/or any suitable combination of the foregoing. A non-exhaustive list of more specific examples of the computer readable storage medium can also include the following: a portable computer diskette, a hard disk, a random access memory (RAM), a read-only memory (ROM), an crasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon and/or any suitable combination of the foregoing. A computer readable storage medium, as used herein, is not to be construed as being transitory signals per se, such as radio waves and/or other freely propagating electromagnetic waves, electromagnetic waves propagating through a waveguide and/or other transmission media (e.g., light pulses passing through a fiber-optic cable), and/or electrical signals transmitted through a wire.

Computer readable program instructions described herein can be downloaded to respective computing/processing devices from a computer readable storage medium and/or to an external computer or external storage device via a network, for example, the Internet, a local area network, a wide area network and/or a wireless network. The network can comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device. Computer readable program instructions for carrying out operations of the one or more embodiments described herein can be assembler instructions, instruction-set-architecture (ISA) instructions, machine instructions, machine dependent instructions, microcode, firmware instructions, state-setting data, configuration data for integrated circuitry, and/or source code and/or object code written in any combination of one or more programming languages, including an object oriented programming language such as Smalltalk, C++ or the like, and/or procedural programming languages, such as the “C” programming language and/or similar programming languages. The computer readable program instructions can execute entirely on a computer, partly on a computer, as a stand-alone software package, partly on a computer and/or partly on a remote computer or entirely on the remote computer and/or server. In the latter scenario, the remote computer can be connected to a computer through any type of network, including a local area network (LAN) and/or a wide area network (WAN), and/or the connection can be made to an external computer (for example, through the Internet using an Internet Service Provider). In one or more embodiments, electronic circuitry including, for example, programmable logic circuitry, field-programmable gate arrays (FPGA) and/or programmable logic arrays (PLA) can execute the computer readable program instructions by utilizing state information of the computer readable program instructions to personalize the electronic circuitry, in order to perform aspects of the one or more embodiments described herein.

Aspects of the one or more embodiments described herein are described with reference to flowchart illustrations and/or block diagrams of methods, apparatus (systems), and computer program products according to one or more embodiments described herein. It will be understood that each block of the flowchart illustrations and/or block diagrams, and combinations of blocks in the flowchart illustrations and/or block diagrams, can be implemented by computer readable program instructions. These computer readable program instructions can be provided to a processor of a general-purpose computer, special purpose computer and/or other programmable data processing apparatus to produce a machine, such that the instructions, which execute via the processor of the computer or other programmable data processing apparatus, can create means for implementing the functions/acts specified in the flowchart and/or block diagram block or blocks. These computer readable program instructions can also be stored in a computer readable storage medium that can direct a computer, a programmable data processing apparatus and/or other devices to function in a particular manner, such that the computer readable storage medium having instructions stored therein can comprise an article of manufacture including instructions which can implement aspects of the function/act specified in the flowchart and/or block diagram block or blocks. The computer readable program instructions can also be loaded onto a computer, other programmable data processing apparatus and/or other device to cause a series of operational acts to be performed on the computer, other programmable apparatus and/or other device to produce a computer implemented process, such that the instructions which execute on the computer, other programmable apparatus and/or other device implement the functions/acts specified in the flowchart and/or block diagram block or blocks.

The flowcharts and block diagrams in the figures illustrate the architecture, functionality and/or operation of possible implementations of systems, computer-implementable methods and/or computer program products according to one or more embodiments described herein. In this regard, each block in the flowchart or block diagrams can represent a module, segment and/or portion of instructions, which comprises one or more executable instructions for implementing the specified logical function. In one or more alternative implementations, the functions noted in the blocks can occur out of the order noted in the Figures. For example, two blocks shown in succession can be executed substantially concurrently, and/or the blocks can sometimes be executed in the reverse order, depending upon the functionality involved. It will also be noted that each block of the block diagrams and/or flowchart illustration, and/or combinations of blocks in the block diagrams and/or flowchart illustration, can be implemented by special purpose hardware-based systems that can perform the specified functions and/or acts and/or carry out one or more combinations of special purpose hardware and/or computer instructions.

While the subject matter has been described above in the general context of computer-executable instructions of a computer program product that runs on a computer and/or computers, those skilled in the art will recognize that the one or more embodiments herein also can be implemented at least partially in parallel with one or more other program modules. Generally, program modules include routines, programs, components and/or data structures that perform particular tasks and/or implement particular abstract data types. Moreover, the aforedescribed computer-implemented methods can be practiced with other computer system configurations, including single-processor and/or multiprocessor computer systems, mini-computing devices, mainframe computers, as well as computers, hand-held computing devices (e.g., PDA, phone), and/or microprocessor-based or programmable consumer and/or industrial electronics. The illustrated aspects can also be practiced in distributed computing environments in which tasks are performed by remote processing devices that are linked through a communications network. However, one or more, if not all aspects of the one or more embodiments described herein can be practiced on stand-alone computers. In a distributed computing environment, program modules can be located in both local and remote memory storage devices.

As used in this application, the terms “component,” “system,” “platform” and/or “interface” can refer to and/or can include a computer-related entity or an entity related to an operational machine with one or more specific functionalities. The entities described herein can be either hardware, a combination of hardware and software, software, or software in execution. For example, a component can be, but is not limited to being, a process running on a processor, a processor, an object, an executable, a thread of execution, a program and/or a computer. By way of illustration, both an application running on a server and the server can be a component. One or more components can reside within a process and/or thread of execution and a component can be localized on one computer and/or distributed between two or more computers. In another example, respective components can execute from various computer readable media having various data structures stored thereon. The components can communicate via local and/or remote processes such as in accordance with a signal having one or more data packets (e.g., data from one component interacting with another component in a local system, distributed system and/or across a network such as the Internet with other systems via the signal). As another example, a component can be an apparatus with specific functionality provided by mechanical parts operated by electric or electronic circuitry, which is operated by a software and/or firmware application executed by a processor. In such a case, the processor can be internal and/or external to the apparatus and can execute at least a part of the software and/or firmware application. As yet another example, a component can be an apparatus that provides specific functionality through electronic components without mechanical parts, where the electronic components can include a processor and/or other means to execute software and/or firmware that confers at least in part the functionality of the electronic components. In an aspect, a component can emulate an electronic component via a virtual machine, e.g., within a cloud computing system.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in the subject specification and annexed drawings should generally be construed to mean “one or more” unless specified otherwise or clear from context to be directed to a singular form. As used herein, the terms “example” and/or “exemplary” are utilized to mean serving as an example, instance, or illustration. For the avoidance of doubt, the subject matter described herein is not limited by such examples. In addition, any aspect or design described herein as an “example” and/or “exemplary” is not necessarily to be construed as preferred or advantageous over other aspects or designs, nor is it meant to preclude equivalent exemplary structures and techniques known to those of ordinary skill in the art.

As it is employed in the subject specification, the term “processor” can refer to substantially any computing processing unit and/or device comprising, but not limited to, single-core processors; single-processors with software multithread execution capability; multi-core processors; multi-core processors with software multithread execution capability; multi-core processors with hardware multithread technology; parallel platforms; and/or parallel platforms with distributed shared memory. Additionally, a processor can refer to an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, and/or any combination thereof designed to perform the functions described herein. Further, processors can exploit nano-scale architectures such as, but not limited to, molecular and quantum-dot based transistors, switches and/or gates, in order to optimize space usage and/or to enhance performance of related equipment. A processor can be implemented as a combination of computing processing units.

Herein, terms such as “store,” “storage,” “data store,” data storage,” “database,” and substantially any other information storage component relevant to operation and functionality of a component are utilized to refer to “memory components,” entities embodied in a “memory,” or components comprising a memory. Memory and/or memory components described herein can be either volatile memory or nonvolatile memory or can include both volatile and nonvolatile memory. By way of illustration, and not limitation, nonvolatile memory can include read only memory (ROM), programmable ROM (PROM), electrically programmable ROM (EPROM), electrically erasable ROM (EEPROM), flash memory and/or nonvolatile random-access memory (RAM) (e.g., ferroelectric RAM (FeRAM). Volatile memory can include RAM, which can act as external cache memory, for example. By way of illustration and not limitation, RAM can be available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), direct Rambus RAM (DRRAM), direct Rambus dynamic RAM (DRDRAM) and/or Rambus dynamic RAM (RDRAM). Additionally, the described memory components of systems and/or computer-implemented methods herein are intended to include, without being limited to including, these and/or any other suitable types of memory.

What has been described above includes mere examples of systems and computer-implemented methods. It is, of course, not possible to describe every conceivable combination of components and/or computer-implemented methods for purposes of describing the one or more embodiments, but one of ordinary skill in the art can recognize that many further combinations and/or permutations of the one or more embodiments are possible. Furthermore, to the extent that the terms “includes,” “has,” “possesses,” and the like are used in the detailed description, claims, appendices and/or drawings such terms are intended to be inclusive in a manner similar to the term “comprising” as “comprising” is interpreted when employed as a transitional word in a claim.

The descriptions of the various embodiments have been presented for purposes of illustration but are not intended to be exhaustive or limited to the embodiments described herein. Many modifications and variations will be apparent to those of ordinary skill in the art without departing from the scope and spirit of the described embodiments. The terminology used herein was chosen to best explain the principles of the embodiments, the practical application and/or technical improvement over technologies found in the marketplace, and/or to enable others of ordinary skill in the art to understand the embodiments described herein.

What is claimed is:

1. A system, comprising:
a memory that stores computer executable components; and
a processor, operably coupled to the memory, that executes the computer executable components stored in the memory, wherein the computer executable components comprise:
a generating component that generates a mixed integer linear programming (MILP) problem model representing a vertex of quantum subcircuits to be subdivided from a quantum circuit; and
a subdividing component that identifies a wire-cutting edge of the quantum circuit using the MILP problem model and based on a decision variable that corresponds to the vertex.

2. The system of claim 1, wherein the subdividing component generates a wire-cutting solution comprising cut data defining a wire cut to be applied to the quantum circuit at the vertex, resulting in subdivision of the quantum circuit into the quantum subcircuits.

3. The system of claim 1, wherein the generating component determines a set of MILP parameters comprising the decision variable absent determination of an additional decision variable corresponding to the wire-cutting edge.

4. The system of claim 1, wherein the generating component determines a set of constraints to be employed by the MILP problem model and defining assignment of the vertex only to a single quantum subcircuit, of the quantum subcircuits.

5. The system of claim 1, wherein the generating component determines a set of wire-cutting parameters defining maximum values for the quantum subcircuits, wherein the wire-cutting parameters comprise at least a maximum number of the quantum subcircuits to employ by the MILP problem model and a maximum size of the quantum subcircuits to employ by the MILP problem model.

6. The system of claim 1, wherein the subdividing component determines a number of wire-cutting edges, including the wire-cutting edge, as being equal to a number of vertices represented by the MILP problem model, including the vertex.

7. The system of claim 1, wherein the generating component determines an objective function to employ for the MILP problem model based on a first decision to consider reconstruction cost of the quantum subcircuits or based on a second decision to consider both the reconstruction cost of the quantum subcircuits and a simulation cost associated with execution of the quantum subcircuits at a quantum computing simulator.

8. The system of claim 2, wherein the computer executable components further comprise:
an evaluating component that, based on user entity feedback data, modifies a wire-cutting parameter employed for generating the wire-cutting solution.

9. The system of claim 1, wherein the computer executable components further comprise:
an executing component that controls executions of the quantum subcircuits at a quantum computing system or at a quantum computing simulator; and
a reconstructing component that generates an outcome of the quantum circuit based on a consolidation of outcomes of the executions.

10. A computer-implemented method, comprising:
generating, by a system operatively coupled to a processor, a mixed integer linear programming (MILP) problem model representing a vertex of quantum subcircuits to be subdivided from a quantum circuit;
identifying, by the system, a wire-cutting edge of the quantum circuit using the MILP problem model and based on a decision variable that corresponds to the vertex.

11. The computer-implemented method of claim 10, further comprising:
generating, by the system, a wire-cutting solution comprising cut data defining a wire cut to be applied to the quantum circuit at the vertex, resulting in subdivision of the quantum circuit into the quantum subcircuits.

12. The computer-implemented method of claim 10, further comprising:
determining, by the system, a set of MILP parameters comprising the decision variable absent determination of an additional decision variable corresponding to the wire-cutting edge.

13. The computer-implemented method of claim 10, further comprising:
prior to the execution, determining, by the system, determines a set of constraints to be employed by the MILP problem model and defining assignment of the vertex only to a single quantum subcircuit.

14. The computer-implemented method of claim 10, further comprising:
determining, by the system, a number of wire-cutting edges, including the wire-cutting edge, as being equal to a number of vertices represented by the MILP problem model, including the vertex.

15. The computer-implemented method of claim 11, further comprising:
based on user entity feedback data, modifying, by the system, a wire-cutting parameter employed for generating the wire-cutting solution.

16. The computer-implemented method of claim 10, further comprising:
controlling, by the system, executions of the quantum subcircuits at a quantum computing system or at a quantum computing simulator; and
determining, by the system, an outcome of the quantum circuit based on a consolidation of outcomes of the executions.

17. A computer program product facilitating a process to determine a quantum circuit wire-cutting solution, the computer program product comprising a computer readable storage medium having program instructions embodied therewith, the program instructions executable by a processor to cause the processor to:
generate, by the processor, a mixed integer linear programming (MILP) problem model representing a vertex of quantum subcircuits to be subdivided from a quantum circuit;
identify, by the processor, a wire-cutting edge of the quantum circuit using the MILP problem model and based on a decision variable that corresponds to the vertex.

18. The computer program product of claim 17, wherein the program instructions are further executable by the processor to cause the processor to:
determine, by the processor, a set of MILP parameters comprising the decision variable absent determination of an additional decision variable corresponding to the wire-cutting edge.

19. The computer program product of claim 17, wherein the program instructions are further executable by the processor to cause the processor to:
determine, by the processor, a set of constraints to be employed by the MILP problem model and defining assignment of the vertex only to a single quantum subcircuit, of the quantum subcircuits.

20. The computer program product of claim 17, wherein the program instructions are further executable by the processor to cause the processor to:
determine, by the processor, a number of wire-cutting edges, including the wire-cutting edge, as being equal to a number of vertices represented by the MILP problem model, including the vertex.
